(19) United States
(12) Patent Application Publication
(10) Pub. No.: US 2011/0114999 A1
(43) Pub. Date: May 19, 2011

(54) SPUTTERING TARGET AND METHOD FOR MANUFACTURING THE SAME, AND TRANSISTOR

(75) Inventors: Shunpei Yamazaki, Tokyo (JP); Toru TAKAYAMA, Kanagawa (JP); Keiji SATO, Kanagawa (JP)

(73) Assignee: SEMICONDUCTOR ENERGY LABORATORY CO., LTD., Kanagawa-ken (JP)

(21) Appl. No.: 12/945,580

(22) Filed: Nov. 12, 2010

(30) Foreign Application Priority Data
Nov. 13, 2009 (JP) 2009-260238

(51) Int. Cl. H01L 29/80; B23K 1/20; C21D 1/34; C23C 14/14

(52) U.S. Cl. 257/280; 228/173.1; 419/29; 204/298.13; 257/E29.311

(57) ABSTRACT

To provide a deposition technique for forming an oxide semiconductor film. An oxide semiconductor film is formed using a sputtering target which contains a sintered body of metal oxide and in which the concentration of hydrogen contained in the sintered body of metal oxide is, for example, as low as 1×10¹⁶ atoms/cm³ or lower, so that the oxide semiconductor film contains a small amount of impurities such as a hydrogen atom and a compound containing a hydrogen atom typified by H₂O. Further, this oxide semiconductor film is used as an active layer of a transistor.

### TECHNICAL FIELD

The present invention relates to a sputtering target and a method for manufacturing the sputtering target. In addition, the present invention relates to a transistor manufactured using the sputtering target.

### BACKGROUND ART

A transistor formed over a flat plate such as a glass substrate, which is typically used in a liquid crystal display device, is generally formed using a semiconductor material such as amorphous silicon or polycrystalline silicon. A transistor manufactured using amorphous silicon has low field effect mobility, but can be formed over a larger glass substrate. In contrast, a transistor manufactured using polycrystalline silicon has high field effect mobility, but needs a crystallization step such as laser annealing and is not always suitable for being formed over a large glass substrate.

In view of the foregoing, a technique in which a transistor is manufactured using an oxide semiconductor as a semiconductor material and applied to an electronic device or an optical device has attracted attention. For example, Patent Document 1 and Patent Document 2 disclose a technique by which a transistor is manufactured using zinc oxide or an In—Ga—Zn—O-based oxide semiconductor as a semiconductor material and such a transistor is used as a switching element or the like of an image display device.

A transistor in which a channel formation region (also referred to as a channel region) is provided in an oxide semiconductor can have higher field effect mobility than a transistor in which amorphous silicon is used. An oxide semiconductor film can be formed by a sputtering method or the like at a relatively low temperature. Its manufacturing process is easier than that of a transistor manufactured using polycrystalline silicon.

Transistors which are manufactured using such an oxide semiconductor over a glass substrate, a plastic substrate, or the like are expected to be applied to display devices such as a liquid crystal display, an electroluminescent display (also referred to as an EL display), and electronic paper.

### REFERENCE

### [Patent Document 1] Japanese Published Patent Application No. 2007-123861

### [Patent Document 2] Japanese Published Patent Application No. 2007-096055

### DISCLOSURE OF INVENTION

However, characteristics of a semiconductor element manufactured using an oxide semiconductor are not yet sufficient. For example, controlled threshold voltage, high operation speed, a relatively easy manufacturing process, and sufficient reliability are required for a transistor manufactured using an oxide semiconductor film.

It is an object of one embodiment of the present invention to provide a deposition technique for forming an oxide semiconductor film. In addition, it is an object of one embodiment of the present invention to provide a method for manufacturing a highly reliable semiconductor element in which the oxide semiconductor film is used.

The threshold voltage of a transistor in which an oxide semiconductor is used is affected by the density of carriers in the oxide semiconductor film. The carriers in the oxide semiconductor film are generated due to impurities contained in the oxide semiconductor film. For example, impurities such as a compound containing a hydrogen atom typified by water (H₂O); a compound containing a carbon atom; a hydrogen atom; or a hydrogen atom which are contained in the oxide semiconductor film formed causes an increase in the density of the carriers in the oxide semiconductor film.

It is difficult to control deterioration over time, such as a shift in the threshold voltage, of a transistor manufactured using the oxide semiconductor film containing impurities such as a hydrogen atom or a compound containing a hydrogen atom typified by water (H₂O).

The inventors thought that in order to achieve the above-described objects, a conductive film, which contains a small amount of impurities such as a compound containing a hydrogen atom typified by water (H₂O) or a hydrogen atom, is used as a conductive film for a source electrode and a drain electrode and is formed over or below an oxide semiconductor film, so that impurities such as hydrogen or water in the oxide semiconductor film are extracted by the conductive film and the purity of the oxide semiconductor film is increased; consequently, deterioration of a transistor over time due to the impurities such as hydrogen or water might be suppressed. The conductive film is processed into a desired shape by etching or the like, so that the source electrode and the drain electrode can be formed.

In view of the above, one embodiment of the present invention is to form a conductive film which contains a small amount of impurities by eliminating impurities which affect the density of carriers in a sputtering target used for deposition, for example, impurities such as a hydrogen atom or a compound containing a hydrogen atom typified by water (H₂O).

A sputtering target according to one embodiment of the present invention is a sputtering target for forming a conductive film. The sputtering target contains a sintered body of a metal material whose electronegativity is lower than that of hydrogen of 2.1. The sintered body contains hydrogen at a concentration of lower than or equal to 1×10¹⁶ atoms/cm³.

Further, a sputtering target according to one embodiment of the present invention is a sputtering target for forming a conductive film. The sputtering target contains a sintered body of a metal material of at least any one of aluminum, copper, chromium, tantalum, titanium, molybdenum, and tungsten. The sintered body contains hydrogen at a concentration lower than or equal to 1×10¹⁶ atoms/cm³.

Further, a sputtering target according to one embodiment of the present invention is a sputtering target for forming a conductive film. The sputtering target contains a sintered body of a metal material in which silicon, titanium, tantalum, tungsten, molybdenum, chromium, neodymium, scandium, or yttrium is mixed with aluminum at 0.1 at. % to 3 at. %. The sintered body contains hydrogen at a concentration lower than or equal to 1×10¹⁶ atoms/cm³.

A transistor according to one embodiment of the present invention includes a conductive film formed using any of the above sputtering targets, in contact with an active layer.

A method for manufacturing a sputtering target according to one embodiment of the present invention includes the steps of forming a sintered body of a metal material by baking the metal material, forming a target with a desired shape by machining the sintered body of the metal material, cleaning the target, and performing heat treatment on the target which has been cleaned.

A method for manufacturing a sputtering target according to one embodiment of the present invention includes the steps of forming a sintered body of a metal material by baking the metal material, forming a target with a desired shape by machining the sintered body of the metal material, cleaning the target, performing heat treatment on the target which has been cleaned, and attaching the target to a backing plate.

Note that in this specification, a sintered body of a metal material which has a desired shape after being machined is referred to as a “target” in some cases. Further, in some cases, a combination of the target and a backing plate is particularly referred to as a “sputtering target”.

The ordinal numbers such as “first” and “second” in this specification are used for convenience and do not denote the order of steps and the stacking order of layers. In addition, the ordinal numbers in this specification do not denote particular names which specify the present invention.

In this specification, “oxynitride” refers to a substance that contains more oxygen atoms than nitrogen atoms and nitride oxide refers to a substance that contains more nitrogen atoms than oxygen atoms. For example, a “silicon oxynitride film” means a film that contains oxygen atoms and nitrogen atoms so that the number of the oxygen atoms is larger than that of the nitrogen atoms and, in the case where measurements are performed using Rutherford backscattering spectrometry (RBS) and hydrogen forward scattering (HFS), contains oxygen, nitrogen, silicon, and hydrogen at concentrations ranging from 50 at. % to 70 at. % inclusive, 0.5 at. % to 15 at. % inclusive, 25 at. % to 35 at. % inclusive, and 0.1 at. % to 10 at. % inclusive, respectively. Further, a “silicon nitride oxide film” means a film that contains nitrogen atoms and oxygen atoms so that the number of the nitrogen atoms is larger than that of the oxygen atoms and, in the case where measurements are performed using RBS and HFS, contains oxygen, nitrogen, silicon, and hydrogen at concentrations ranging from 5 at. % to 30 at. % inclusive, 20 at. % to 55 at. % inclusive, 25 at. % to 35 at. % inclusive, and 10 at. % to 30 at. % inclusive, respectively. Note that percentages of nitrogen, oxygen, silicon, and hydrogen fall within the ranges given above, where the total number of atoms contained in the silicon oxynitride film or the silicon nitride oxide film is defined as 100 at. %.

In this specification and the like, the terms “over” and “below” do not necessarily mean “directly on” and “directly below”, respectively, in the description of a physical relationship between components. For example, the expression of “a first gate electrode over a gate insulating layer” does not exclude the case where another component is interposed between the gate insulating layer and the gate electrode. In addition, the terms “over” and “below” are used only for convenience of the description. Unless otherwise specified, the case where the positions thereof are interchanged is included.

In addition, in this specification and the like, the term such as “electrode” or “wiring” does not limit a function of a component. For example, an “electrode” is sometimes used as part of a “wiring”, and vice versa. Furthermore, the term “electrode” or “wiring” can include the case where a plurality of “electrodes” or “wirings” are formed in an integrated manner.

Functions of a “source” and a “drain” are sometimes replaced with each other when a transistor of opposite polarity is used or when the direction of current flowing is changed in circuit operation, for example. Therefore, the terms “source” and “drain” can be replaced with each other in this specification.

Note that in this specification, the concentration of hydrogen in a target, an oxide semiconductor film, or a conductive film is measured by secondary ion mass spectrometry (SIMS). Note that it is known that it is difficult, in principle, to obtain correct data in the proximity of a surface of a sample or in the proximity of an interface between stacked films formed using different materials by the SIMS analysis. Thus, in the case where distributions of the hydrogen concentrations of the films in thickness directions are analyzed by SIMS, an average value in a region where the films are provided, the value is not greatly changed, and substantially the same strength can be obtained is employed as the hydrogen concentration. Further, in the case where the thickness of the film is small, a region where substantially the same strength can be obtained cannot be found in some cases due to the influence of the concentration of hydrogen in the films adjacent to each other. In that case, the maximum value or the minimum value of the hydrogen concentration of a region where the films are provided is employed as the hydrogen concentration of the film. Furthermore, in the case where a mountain-shaped peak having the maximum value and a valley-shaped peak having the minimum value do not exist in the region where the films are provided, the value of the inflection point is employed as the hydrogen concentration.

According to one embodiment of the present invention, a sputtering target which contains a small amount of impurities such as a hydrogen atom or a compound containing a hydrogen atom typified by water (H₂O) can be provided. Further, a conductive film in which the amount of impurities is reduced can be formed using the sputtering target. Further, a method for manufacturing a highly reliable semiconductor element in which an oxide semiconductor film formed in contact with the conductive film is used as an active layer can be provided.

### BRIEF DESCRIPTION OF DRAWINGS

In the accompanying drawings:

FIGS. 1A to 1F are a flowchart of a method for manufacturing a sputtering target;

FIG. 2A is a plan view of a transistor according to Embodiment and FIG. 2B is a cross-sectional view thereof;

FIGS. 3A to 3E illustrate a manufacturing process of a transistor according to Embodiment;

FIG. 4A is a plan view of a transistor according to Embodiment and FIG. 4B is a cross-sectional view thereof;

FIGS. 5A to 5E illustrate a manufacturing process of a transistor according to Embodiment;

FIGS. 6A and 6B are cross-sectional views of transistors according to Embodiment;

FIGS. 7A to 7E illustrate a manufacturing process of a transistor according to Embodiment;

FIGS. 8A to 8E illustrate a manufacturing process of a transistor according to Embodiment;

FIGS. 9A to 9D illustrate a manufacturing process of a transistor according to Embodiment;

FIGS. 10A to 10D illustrate a manufacturing process of a transistor according to Embodiment;

FIG. 11 is a cross-sectional view of a transistor according to Embodiment;

FIG. 12 is a cross-sectional view of a transistor including an oxide semiconductor;

FIG. 13 is an energy band diagrams (schematic diagrams) along an A-A′ section in FIG. 12;

FIG. 14A shows a diagram illustrating a state where a positive potential (V_{G}>0) is applied to a gate electrode (GE1) and FIG. 14B is a diagram illustrating a state where a negative potential (V_{G}<0) is applied to the gate electrode (GE1);

FIG. 15 shows a diagram illustrating the relation between the vacuum level and the work function of a metal (φ_{M}) and between the vacuum level and the electron affinity (χ) of an oxide semiconductor; and

FIGS. 16A to 16F illustrate electronic devices.

### BEST MODE FOR CARRYING OUT THE INVENTION

Hereinafter, Embodiments of the present invention will be described in detail below with reference to the accompanying drawings. The present invention is not limited to the description below, and it is easily understood by those skilled in the art that modes and details disclosed herein can be modified in various ways without departing from the spirit and scope of the present invention. Note that in the drawings of this specification, the identical portions or portions having a similar function are denoted by the identical reference numerals, and description thereon may be omitted.

### Embodiment 1

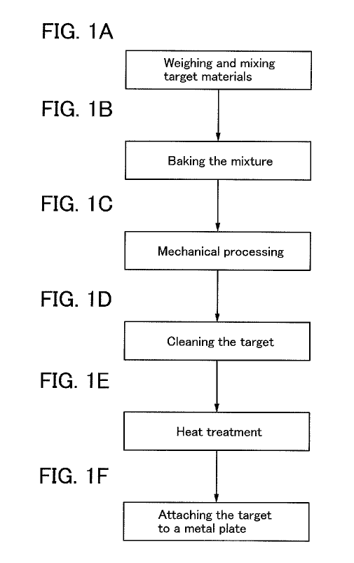

In this embodiment, a method for manufacturing a sputtering target (hereinafter, also referred to as a target) that is one embodiment of the present invention will be described with reference to FIGS. 1A to 1F. FIGS. 1A to 1F are a flow chart illustrating an example of a method for manufacturing a sputtering target according to this embodiment.

First, target materials are weighed as appropriate, and the weighed target materials are mixed while they are crushed in a ball mill or the like (FIG. 1A). As a material for a target for forming a conductive film, which is described in this embodiment, for example, a material can be used, in which an element which prevents hillocks or whiskers from being generated on an aluminum film, such as silicon (Si), titanium (Ti), tantalum (Ta), tungsten (W), molybdenum (Mo), chromium (Cr), neodymium (Nd), scandium (Sc), yttrium (Y), or a lanthanum material is mixed with aluminum (Al) powder at 0.1 at. % to 3 at. %.

Note that the material that can be used for the target is not limited to the above materials, and a metal material such as aluminum (Al), copper (Cu), chromium (Cr), tantalum (Ta), titanium (Ti), molybdenum (Mo), or tungsten (W) can be used alone or in combination as appropriate. Note that a metal material having a low electronegativity, specifically a metal material having a lower electronegativity than hydrogen, such as aluminum, titanium, chromium, copper, or tantalum, is preferably used, in which case, when a conductive film is formed in contact with an oxide semiconductor film, impurities such as moisture or hydrogen are easily extracted from the oxide semiconductor film. Among the metal materials having a low electronegativity given above, titanium is particularly preferable because of its low contact resistance with an oxide semiconductor film.

Alternatively, conductive metal oxide may be used as the target material. As the conductive metal oxide, indium oxide (In₂O₃), tin oxide (SnO₂), zinc oxide (ZnO), an indium oxide-tin oxide (In₂O₃—SnO₂, abbreviated to ITO) alloy, an indium oxide-zinc oxide (In₂O₃—ZnO) alloy, or the like can be used. Further alternatively, as the target material, silicon or silicon oxide may be added to a metal oxide material.

Next, the mixture is formed into a predetermined shape and baked, so that a sintered body of the metal material is obtained (FIG. 1B). When the target material is baked, hydrogen, moisture, hydrocarbon, or the like can be prevented from being mixed into the target. The baking can be performed in an inert gas atmosphere (e.g., a nitrogen atmosphere or a rare gas atmosphere), in vacuum, or in a high-pressure atmosphere, and may be performed while mechanical pressure is applied. As a baking method, an atmospheric sintering method, a pressure sintering method, or the like can be used as appropriate. A hot pressing method, a hot isostatic pressing (HIP) method, a discharge plasma sintering method, or an impact method is preferably used as a pressure sintering method. Although the maximum temperature of the baking is selected in accordance with the sintering temperature of the target material, it is preferably approximately 1000° C. to 2000° C., more preferably 1200° C. to 1500° C. In addition, although the period in which the maximum temperature is held is selected in accordance with the target material, it is preferably 0.5 hours to 3 hours.

Note that the filling rate of a metal target of this embodiment is preferably greater than or equal to 90% and less than or equal to 100%, more preferably greater than or equal to 95% and less than or equal to 99.9%. A metal target with high filling rate makes it possible to remove cavities that allow impurities such as moisture to be adsorbed on the target at the time of sputtering deposition. In addition, during sputtering deposition, generation of nodules can be prevented, uniform discharge can be performed, and generation of particles can be suppressed. Furthermore, the smoothness of a surface of a formed conductive film is favorable.

Next, mechanical processing is performed in order to obtain a target having desired dimensions, shape, and surface roughness (FIG. 1C). As a processing means, for example, mechanical polishing, chemical mechanical polishing (CMP), or a combination of these can be used.

After that, in order to remove minute dust and components of a grinding solution generated by the mechanical processing, the target is cleaned by ultrasonic cleaning in which the target is soaked in water or an organic solvent, cleaning with running water, or the like (FIG. 1D). By performing cleaning after the mechanical processing, a target from which dust and impurities have been removed can be obtained, and a film with high purity and high quality can be formed using the target.

Next, heat treatment is performed on the target after being cleaned (FIG. 1E). The heat treatment is preferably performed in an inert gas atmosphere (e.g., a nitrogen atmosphere or a rare gas atmosphere). The temperature of the heat treatment differs depending on the target material, the temperature at which the target material does not get denatured and hydrogen or moisture on a surface of the target or in the target is sufficiently eliminated is employed. Specifically, the temperature is higher than or equal to 150° C. and lower than or equal to 750° C., preferably higher than or equal to 425° C. and lower than or equal to 750° C. The heating period is set so that the concentration of hydrogen in the target can be sufficiently reduced, and specifically is 0.5 hours or more, preferably 1 hour or more. The heat treatment after the cleaning makes it possible to eliminate hydrogen, moisture, or the like mixed into the target due to the cleaning can be eliminated from the target. Note that the heat treatment may be performed in vacuum or in a high-pressure atmosphere.

For example, the target is introduced into an electric furnace that is a kind of heat treatment apparatus, heat treatment is performed in a nitrogen atmosphere, and then the target is prevented from being exposed to air so that entry of water or hydrogen into the target is prevented, whereby a target in which the nitrogen concentration is reduced is obtained. Slow cooling is performed in one furnace in a nitrogen atmosphere from heating temperature T to a temperature low enough to prevent entry of water; specifically, the slow cooling is performed in a nitrogen atmosphere until the temperature drops by 100° C. or more from heating temperature T. The heat treatment is performed in a helium atmosphere, a neon atmosphere, an argon atmosphere, or the like without limitation to a nitrogen atmosphere.

Note that the heat treatment apparatus is not limited to the electric furnace and may be, for example, a rapid thermal annealing (RTA) apparatus such as a gas rapid thermal annealing (GRTA) apparatus or a lamp rapid thermal annealing (LRTA) apparatus. An LRTA apparatus is an apparatus for heating an object to be processed by radiation of light (electromagnetic waves) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heating an object to be processed by thermal radiation using light emitted from the above-described lamp and by conduction of heat from a gas heated by light emitted from a lamp. As the gas, an inert gas which does not react with an object to be processed by heat treatment, such as nitrogen or a rare gas such as argon is used. In addition, the LRTA apparatus and the GRTA apparatus may be provided with a device that heats the product by heat conduction or heat radiation from not only a lamp but also a heater such as a resistance heater.

Note that in the heat treatment, it is preferable that moisture, hydrogen, and the like be not contained in nitrogen or a rare gas such as helium, neon, or argon. It is preferable that the purity of nitrogen or the rare gas such as helium, neon, or argon which is introduced into a heat treatment apparatus be set to be 6N (99.9999%) or higher, preferably 7N (99.99999%) or higher (that is, the impurity concentration is 1 ppm or lower, preferably 0.1 ppm or lower).

The hydrogen concentration of the metal target described in this embodiment, which is measured by secondary ion mass spectrometry (SIMS), can be 5×10¹⁹ atoms/cm³ or lower, preferably 5×10¹⁸ atoms/cm³ or lower, more preferably 5×10¹⁷ atoms/cm³ or lower or 1×10¹⁶ atoms/cm³ or lower by the heat treatment performed after the cleaning. Thus, the concentration of hydrogen in the conductive film formed using the target can be reduced.

After that, the target is attached to a metal plate called a backing plate (FIG. 1F). A backing plate has functions of cooling a target material and being a sputtering electrode, and thus is preferably formed using copper, which is excellent in thermal conductivity and electric conductivity. Alternatively, titanium, a copper alloy, a stainless steel alloy, or the like can be used instead of copper. A cooling path is formed inside or on the back surface of the backing plate, and water, oil, or the like circulates through the cooling path as a coolant; thus, the cooling efficiency of a target at the time of sputtering deposition can be increased. Note that water vaporizes at 100° C.; therefore, in the case where the temperature of the target needs to be kept at 100° C. or higher, oil or the like is preferable to water.

The target can be attached to the backing plate by, for example, electron beam welding. The electron beam welding refers to a method in which electrons generated in a vacuum atmosphere are accelerated, focused, and then delivered to an object, whereby welding can be performed only on a portion which is desired to be welded without damage on the material property of portions of the object except for the welded portion. In the electron beam welding, the shape of the welded portion and the depth of welding can be controlled. Since the welding is performed in vacuum, hydrogen, moisture, hydrocarbon, and the like can be prevented from attaching to the target.

As a brazing material for attaching the target to the backing plate, metal (Au), bismuth (Bi), tin (Sn), zinc (Zn), or indium (In), an alloy thereof, a low-melting-point alloy solder, or the like can be preferably used. Note that a metal (or alloy) material with high conductivity is preferably used as a brazing material. Further, a back coat layer may be formed between the brazing material and the target. The formation of the back coat layer makes it possible to improve the adhesion between the target and the backing plate.

In this embodiment, an example in which heat treatment after cleaning is performed before the attachment of the target to the backing plate is described; however, the embodiments of the present invention are not limited thereto, and heat treatment may be performed after the attachment of the target and the backing plate or may be performed plural times before and after the attachment. Note that it is preferable that heat treatment after the attachment of the target and the backing plate be performed at higher than or equal to 150° C. and lower than or equal to 350° C., in consideration of the heat resistance of the brazing material or the backing plate. Heat treatment is preferably performed in an inert gas atmosphere (a nitrogen atmosphere or a rare gas atmosphere).

It is preferable that the target which has been subjected to heat treatment be transferred, stored, and the like in a high-purity oxygen gas atmosphere, a high-purity nitrous oxide (N₂O) gas atmosphere, or an ultra dry air (having a dew point of −40° C. or lower, preferably −60° C. or lower) atmosphere, in order to prevent entry of moisture or hydrogen. The target may be covered with a protective material formed of a material with low water permeability such as a stainless steel alloy, and the above gas may be introduced into a gap between the protective material and the target. It is preferable that the oxygen gas and the nitrous oxide (N₂O) gas do not contain water, hydrogen, and the like. Alternatively, the purity of an oxygen gas or a nitrous oxide (N₂O) gas is preferably 6N (99.9999%) or higher, more preferably 7N (99.99999%) or higher (that is, the impurity concentration of the oxygen gas or the nitrous oxide (N₂O) gas is 1 ppm or lower, preferably 0.1 ppm or lower).

Through the above-described steps, the sputtering target in this embodiment can be manufactured. In the manufacturing process, heat treatment is performed on the sputtering target described in this embodiment after the cleaning, whereby impurities such as a hydrogen atom or a compound containing a hydrogen atom are eliminated, which results in a reduction in impurities. Therefore, the impurities contained in a conductive film formed using the target can also be reduced.

The conductive film is used as a conductive film for forming source and drain electrodes of a transistor and is formed over or below an oxide semiconductor film used as an active layer, so that impurities such as hydrogen or water in the oxide semiconductor film are extracted by the conductive film, which allows the purity of the oxide semiconductor film to be increased. As a result, a transistor whose deterioration over time due to impurities such as hydrogen or moisture is suppressed can be manufactured. Further, a metal having a lower electronegativity than hydrogen is used as a material used for the conductive film, so that a larger amount of impurities can be extracted.

Note that impurities such as a hydrogen atom may be eliminated by irradiation using a UV lamp in vacuum instead of heat treatment, or irradiation using a UV lamp and heat treatment may be used in combination.

Similarly, the target is set in a sputtering apparatus in an inert gas atmosphere (a nitrogen atmosphere or a rare gas atmosphere) without being exposed to air, so that hydrogen, moisture, hydrocarbon, or the like can be prevented from attaching to the target.

After the target is set in the sputtering apparatus, dehydrogenation treatment is preferably performed to remove hydrogen which remains on a surface of or inside the target material. As the dehydrogenation treatment, a method in which the inside of a film formation chamber is heated to 200° C. to 600° C. under reduced pressure, a method in which introduction and removal of nitrogen or an inert gas are repeated while heating is performed, and the like can be given. In this case, not water but oil or the like is preferably used as a coolant for the target. Although a certain level of effect can be obtained when introduction and removal of nitrogen are repeated without heating, it is preferable to perform the treatment while heating is performed. Alternatively, oxygen, an inert gas, or both oxygen and an inert gas may be introduced into the film formation chamber, and plasma of an inert gas and/or oxygen may be generated using high-frequency waves or microwaves. Although a certain level of effect can be obtained when the treatment is performed without heating, it is preferable to perform the treatment while heating is performed.

Note that this embodiment can be combined with any of the other Embodiments as appropriate.

### Embodiment 2

In this embodiment, an example of manufacturing a transistor as a semiconductor device manufactured using the target in Embodiment 1 will be described. In a transistor 410 described in this embodiment, a conductive formed using the sputtering target described in Embodiment 1 can be used as a conductive film for forming a source electrode and a drain electrode.

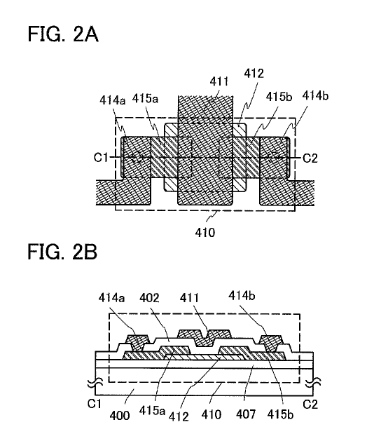

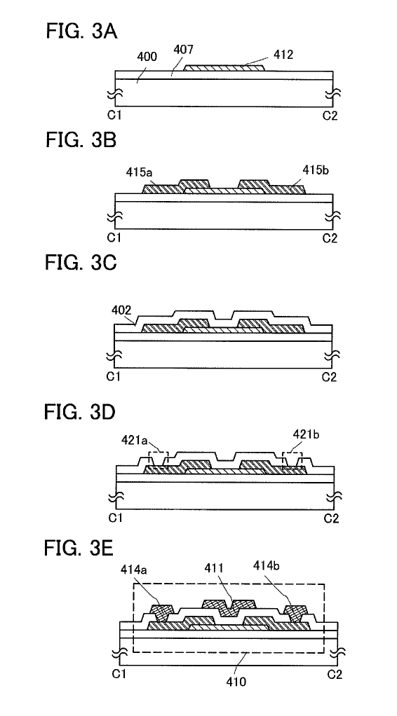

One embodiment of a transistor and one embodiment of a method for manufacturing the transistor according to this embodiment will be described with reference to FIGS. 2A and 2B and FIGS. 3A to 3E.

Examples of a plan structure and a cross-sectional structure of a transistor are respectively illustrated in FIGS. 2A and 2B. The transistor 410 illustrated in FIGS. 2A and 2B is one of top-gate transistors.

FIG. 2A is a plan view of the top-gate transistor 410 and FIG. 2B is a cross-sectional view taken along line C₁-C₂ in FIG. 2A.

The transistor 410 includes, over a substrate 400, an insulating layer 407, an oxide semiconductor layer 412, a source or drain electrode layer 415a, a source or drain electrode layer 415b, a gate insulating layer 402, and a gate electrode layer 411. A wiring layer 414a and a wiring layer 414b are provided in contact with and electrically connect to the source or drain electrode layer 415a and the source or drain electrode layer 415b, respectively.

Although the transistor 410 is described as a single-gate transistor, a multi-gate transistor including a plurality of channel formation regions can be formed when needed.

A process of manufacturing the transistor 410 over a substrate 400 will be described below with reference to FIGS. 3A to 3E.

Although there is no particular limitation on a substrate that can be used as the substrate 400 having an insulating surface, it is necessary that the substrate have at least heat resistance high enough to withstand heat treatment performed later. A glass substrate made of barium borosilicate glass, aluminoborosilicate glass, or the like can be used.

In the case where the temperature of the heat treatment performed later is high, a glass substrate whose strain point is higher than or equal to 730° C. is preferably used. As a material for the glass substrate, for example, a glass material such as aluminosilicate glass, aluminoborosilicate glass, or barium borosilicate glass is used. Note that, in general, in the case where a larger amount of barium oxide (BaO) than boron oxide is contained, a more practical heat-resistant glass substrate can be obtained. Therefore, a glass substrate containing a larger amount of barium oxide (BaO) than boron oxide (B₂O₃) is preferably used.

Note that a substrate formed of an insulator such as a ceramic substrate, a quartz substrate, or a sapphire substrate may be used instead of the above glass substrate. Alternatively, a crystallized glass substrate or the like can be used. Further alternatively, a plastic substrate or the like can be used as appropriate.

First, the insulating layer 407 serving as a base film is formed over the substrate 400 having an insulating surface. As the insulating layer 407 that in contact with the oxide semiconductor layer, an oxide insulating layer such as a silicon oxide layer, a silicon oxynitride layer, an aluminum oxide layer, or an aluminum oxynitride layer is preferably used. As a method for forming the insulating layer 407, a plasma CVD method, a sputtering method, or the like can be used; however, it is preferable that the insulating layer 407 be formed by a sputtering method so that the insulating layer 407 does not contain a large amount of hydrogen.

In this embodiment, a silicon oxide layer is formed as the insulating layer 407 by a sputtering method. A silicon oxide layer is formed as the insulating layer 407 over the substrate 400 in such a manner that the substrate 400 is transferred to a treatment chamber, a sputtering gas which contains high-purity oxygen and from which hydrogen and moisture have been removed is introduced thereinto, and a silicon target is used. The temperature of the substrate 400 may be room temperature, or the substrate 400 may be heated.

For example, a silicon oxide layer is formed by an RF sputtering method under the conditions that quartz (preferably, synthetic quartz) is used, the substrate temperature is 108° C., the distance between the substrate and the target (T-S distance) is 60 mm, the pressure is 0.4 Pa, the high-frequency power is 1.5 kW, and the atmosphere is an atmosphere containing oxygen and argon (the flow ratio of oxygen to argon is 1:1 (each flow rate is 25 sccm)). The thickness of the silicon oxide layer is 100 nm. Note that instead of quartz (preferably, synthetic quartz), a silicon target can be used as a target for forming the silicon oxide layer. As a sputtering gas, oxygen or a mixed gas of oxygen and argon is used.

In this case, it is preferable that the insulating layer 407 be formed while moisture remaining in the treatment chamber is removed so that the insulating layer 407 does not contain hydrogen, hydroxyl groups, or moisture.

In order to remove moisture remaining in the treatment chamber, an entrapment vacuum pump is preferably used. For example, a cryopump, an ion pump, or a titanium sublimation pump is preferably used. An evacuation unit may be a turbo pump provided with a cold trap. From the treatment chamber evacuated using a cryopump, a hydrogen atom, a compound containing a hydrogen atom such as water (H₂O), and the like, for example, are removed; thus, the concentration of impurities in the insulating layer 407 formed in the treatment chamber can be reduced.

As a sputtering gas used in forming the insulating layer 407, a high-purity gas is preferably used, in which impurities such as hydrogen, water, hydroxyl groups, or hydride are removed so that the concentration is approximately several parts per million or approximately several parts per billion.

Examples of a sputtering method include an RF sputtering method in which a high-frequency power source is used for a sputtering power supply, a DC sputtering method in which a DC power source is used, and a pulsed DC sputtering method in which a bias is applied in a pulsed manner. An RF sputtering method is mainly used in the case where an insulating film is formed, and a DC sputtering method is mainly used in the case where a metal film is formed.

In addition, there is also a multi-source sputtering apparatus in which a plurality of targets of different materials can be set. With the multi-source sputtering apparatus, films of different materials can be formed to be stacked in the same chamber, or a film of plural kinds of materials can be formed by electric discharge at the same time in the same chamber.

In addition, there are a sputtering apparatus provided with a magnet system inside the chamber and used for a magnetron sputtering method, and a sputtering apparatus used for an ECR sputtering method in which plasma generated with the use of microwaves is used without using glow discharge.

Further, as examples of a deposition method using a sputtering method, there are a reactive sputtering method in which a target substance and a sputtering gas component are chemically reacted with each other during deposition to form a thin compound film thereof, and a bias sputtering method in which a voltage is also applied to a substrate during deposition.

The insulating layer 407 can also have a stacked-layer structure. For example, a nitride insulating layer such as a silicon nitride layer, a silicon nitride oxide layer, an aluminum nitride layer, or an aluminum nitride oxide layer and the above-described oxide insulating layer may be stacked in this order over the substrate 400.

For example, a silicon nitride layer is formed using a silicon target by introducing a sputtering gas which contains high-purity nitrogen and from which hydrogen and moisture have been removed, to a space between the silicon oxide layer and the substrate. In this case also, it is preferable that the silicon nitride layer be formed while moisture remaining in the treatment chamber is removed in a manner similar to that of the silicon oxide layer.

Also in the case where the silicon nitride layer is formed, the substrate may be heated at the time of deposition.

In the case where the silicon nitride layer and the silicon oxide layer are stacked to form the insulating layer 407, the silicon nitride layer and the silicon oxide layer can be formed in one treatment chamber with the use of the same silicon target. First, a sputtering gas containing nitrogen is introduced and a silicon nitride layer is formed using a silicon target placed inside the treatment chamber, and then the sputtering gas is switched to a sputtering gas containing oxygen and a silicon oxide layer is formed using the same silicon target. Since the silicon nitride layer and the silicon oxide layer can be formed in succession without exposure to air, impurities such as hydrogen or moisture can be prevented from being adsorbed on a surface of the silicon nitride layer.

Next, an oxide semiconductor film is formed to a thickness greater than or equal to 2 nm and less than or equal to 200 nm over the insulating layer 407.

In order that hydrogen, hydroxyl, and moisture are contained as little as possible in the oxide semiconductor film, it is preferable that the substrate 400 over which the insulating layer 407 is formed be preheated in a preheating chamber of the sputtering apparatus, so that impurities such as hydrogen or moisture adsorbed on the substrate 400 are eliminated and removed, as pretreatment for deposition. As an evacuation unit provided for the preheating chamber, a cryopump is preferably used. Note that this preheating treatment can be omitted. This preheating may be similarly performed on the substrate 400 over which the gate insulating layer 402 has not formed yet, or on the substrate 400 over which the source or drain electrode layer 415a and the source or drain electrode layer 415b have not formed yet.

Note that before the oxide semiconductor film is formed by a sputtering method, dust attached to a surface of the insulating layer 407 is preferably removed by reverse sputtering in which plasma is generated by introduction of an argon gas. The reverse sputtering refers to a method in which, without application of voltage to a target side, a high-frequency power source is used for application of voltage to a substrate side in an argon atmosphere and plasma is generated in the vicinity of the substrate to modify a surface. Note that instead of an argon atmosphere, a nitrogen atmosphere, a helium atmosphere, an oxygen atmosphere, or the like may be used.

As the oxide semiconductor film, a four-component metal oxide film such as an In—Sn—Ga—Zn—O-based film; a three-component metal oxide film such as an In—Ga—Zn—O-based film, an In—Sn—Zn—O-based film, an In—Al—Zn—O-based film, a Sn—Ga—Zn—O-based film, an Al—Ga—Zn—O-based film, or a Sn—Al—Zn—O-based film; or a two-component metal oxide film such as an In—Zn—O-based film, a Sn—Zn—O-based film, an Al—Zn—O-based film, a Zn—Mg—O-based film, a Sn—Mg—O-based film, or an In—Mg—O-based film; or a single-component metal oxide film such as an In—O-based film, a Sn—O-based film, or a Zn—O-based film can be used. In addition, the above oxide semiconductor film may contain SiO₂.

As the oxide semiconductor film, a thin film represented by InMO₃ (ZnO)ₘ (m>0) can be used. Here, M represents one or more metal elements selected from gallium (Ga), aluminum (Al), manganese (Mn), and cobalt (Co). For example, M can be gallium (Ga), gallium (Ga) and aluminum (Al), gallium (Ga) and manganese (Mn), gallium (Ga) and cobalt (Co), or the like. An oxide semiconductor film whose composition formula is represented by InMO₃ (ZnO)ₘ (m>0) where at least Ga is contained as M is referred to as the In—Ga—Zn—O-based oxide semiconductor described above, and a thin film thereof is also referred to as an In—Ga—Zn—O-based film.

As a sputtering gas used in forming the oxide semiconductor film, a high-purity gas is preferably used, in which impurities such as hydrogen, water, hydroxyl groups, or hydride are removed so that the concentration is approximately several parts per million or approximately several parts per billion.

As a target for forming the oxide semiconductor film by a sputtering method, an oxide semiconductor target for film formation including zinc oxide as a main component can be used. As another example of an oxide semiconductor target for film formation, an oxide semiconductor target for film formation including In, Ga, and Zn (composition ratio of In₂O₃:Ga₂O₃:ZnO=1:1:1 (molar ratio)) can be used. As the oxide semiconductor target for film formation containing In, Ga, and Zn, a target having a composition ratio of In₂O₃:Ga₂O₃:ZnO=1:1:2 (molar ratio) or a target having a composition ratio of In₂O₃:Ga₂O₃:ZnO=1:1:4 (molar ratio) can also be used. The filling rate of the oxide semiconductor target for film formation is higher than or equal to 90% and lower than or equal to 100%, preferably higher than or equal to 95% and lower than or equal to 99.9%. With the use of the oxide semiconductor target for film formation with a high filling rate, a dense oxide semiconductor film is formed.

The oxide semiconductor film is formed over the substrate 400 in such a manner that the substrate is held in the treatment chamber maintained at reduced pressure, a sputtering gas from which hydrogen and moisture have been removed is introduced into the treatment chamber while moisture remaining therein is removed, and metal oxide is used as a target. In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber which is evacuated with a cryopump, a hydrogen atom, a compound containing a hydrogen atom such as water (H₂O) (preferably also a compound containing a carbon atom), and the like are removed, whereby the concentration of impurities in the oxide semiconductor film formed in the treatment chamber can be reduced. The substrate may be heated when the oxide semiconductor film is formed.

As an example of the deposition condition, the following conditions are employed: the substrate temperature is room temperature, the distance between the substrate and the target is 110 mm, the pressure is 0.4 Pa, and the direct-current (DC) power is 0.5 kW, and the atmosphere is an atmosphere containing oxygen and argon (the flow rate of oxygen is 15 sccm and the flow rate of argon is 30 sccm). Note that a pulsed direct-current (DC) power source is preferably used, in which case powder substances (also referred to as particles or dust) that are generated in deposition can be reduced and the thickness can be uniform. The oxide semiconductor film preferably has a thickness greater than or equal to 5 nm and less than or equal to 30 nm. Note that the appropriate thickness differs depending on the oxide semiconductor material, and the thickness may be set as appropriate depending on the material.

Next, the oxide semiconductor film is processed into an island-shaped oxide semiconductor layer 412 in a first photolithography step (see FIG. 3A). A resist mask for forming the island-shaped oxide semiconductor layer 412 may be formed by an inkjet method. Formation of the resist mask by an inkjet method needs no photomask, which results in a reduction in manufacturing costs.

Note that the etching of the oxide semiconductor film here may be performed by dry etching, wet etching, or both wet etching and dry etching.

As an etching gas for dry etching, a gas containing chlorine (chlorine-based gas such as chlorine (Cl₂), boron chloride (BCl₃), silicon chloride (SiCl₄), or carbon tetrachloride (CCl₄) is preferably used.

Alternatively, a gas containing fluorine (fluorine-based gas such as carbon tetrafluoride (CF₄), sulfur hexafluoride (SF₆), nitrogen trifluoride (NF₃), or trifluoromethane (CHF₃)); hydrogen bromide (HBr); oxygen (O₂); any of these gases to which a rare gas such as helium (He) or argon (Ar) is added; or the like can be used.

As the dry etching method, a parallel plate RIE (reactive ion etching) method or an ICP (inductively coupled plasma) etching method can be used. In order to etch the films into desired shapes, the etching conditions (the amount of electric power applied to a coil-shaped electrode, the amount of electric power applied to an electrode on a substrate side, the temperature of the electrode on the substrate side, and the like) are adjusted as appropriate.

As an etchant used for wet etching, a mixed solution of phosphoric acid, acetic acid, and nitric acid, or the like can be used. Alternatively, ITO07N (produced by KANTO CHEMICAL CO., INC.) may be used.

The etchant used in the wet etching is removed together with the etched materials by cleaning. The waste liquid containing the etchant and the material etched off may be purified and the material may be reused. A material such as indium contained in the oxide semiconductor layer is collected from the waste liquid after the etching and is reused, so that the resources can be efficiently used and the cost can be reduced.

The etching conditions (such as an etchant, etching time, and temperature) are adjusted as appropriate depending on the material so that the oxide semiconductor film can be etched into a desired shape.

In this embodiment, the oxide semiconductor film is processed into the island-shaped oxide semiconductor layer 412 by a wet etching method using a mixed solution of phosphoric acid, acetic acid, and nitric acid as an etchant.

Next, first heat treatment is performed on the oxide semiconductor layer 412. The temperature of the first heat treatment is higher than or equal to 400° C. and lower than or equal to 750° C., preferably higher than or equal to 400° C. and lower than the strain point of the substrate. Here, the substrate is put in an electric furnace that is a kind of heat treatment apparatus and heat treatment is performed on the oxide semiconductor layer at 450° C. in a nitrogen atmosphere for one hour, and then water and hydrogen are prevented from entering the oxide semiconductor layer with the oxide semiconductor layer not exposed to air, so that the oxide semiconductor layer is obtained. Through the first heat treatment, the oxide semiconductor layer 412 can be dehydrated or dehydrogenated, so that the oxide semiconductor layer becomes an intrinsic (i-type) semiconductor or a substantially i-type semiconductor. Thus, deterioration of the characteristics of the transistor due to the impurities, such as a shift in the threshold voltage can be prevented from being promoted, and off-state current can be reduced.

Note that the heat treatment apparatus is not limited to an electronic furnace, and may be provided with a device that heats an object to be processed by heat conduction or heat radiation from a heating element such as a resistance heating element. For example, a rapid thermal annealing (RTA) apparatus such as a gas rapid thermal annealing (GRTA) apparatus or a lamp rapid thermal annealing (LRTA) apparatus can be used. An LRTA apparatus is an apparatus for heating an object to be processed by radiation of light (electromagnetic waves) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. As the gas, an inert gas which does not react with an object to be processed by heat treatment, such as nitrogen or a rare gas such as argon is used.

For example, as the first heat treatment, GRTA may be performed as follows: the substrate is transferred and put in an inert gas which has been heated to a temperature as high as 650° C. to 700° C., heated for several minutes, and transferred and taken out of the inert gas which has been heated to a high temperature. GRTA enables a high-temperature heat treatment in a short time.

Note that in the first heat treatment, it is preferable that water, hydrogen, and the like be not contained in the atmosphere of nitrogen or a rare gas such as helium, neon, or argon. It is preferable that the purity of nitrogen or the rare gas such as helium, neon, or argon which is introduced into a heat treatment apparatus be set to be 6N (99.9999%) or higher, preferably 7N (99.99999%) or higher (that is, the impurity concentration is 1 ppm or lower, preferably 0.1 ppm or lower).

Further, the oxide semiconductor layer might be crystallized to become a microcrystalline film or a polycrystalline film depending on the condition of the first heat treatment or the material for the oxide semiconductor layer. For example, the oxide semiconductor layer might be crystallized to become a microcrystalline oxide semiconductor film having a degree of crystallization of 90% or more, or 80% or more. Further, depending on the condition of the first heat treatment and the material for the oxide semiconductor layer, the oxide semiconductor layer might become an amorphous oxide semiconductor film containing no crystalline component. The oxide semiconductor layer may become an oxide semiconductor film in which a microcrystalline portion (with a grain diameter greater than or equal to 1 nm and greater than or less than 20 nm, typically greater than or equal to 2 nm and less than or equal to 4 nm) is mixed into an amorphous oxide semiconductor.

The first heat treatment for the oxide semiconductor layer can be performed on the oxide semiconductor film that has not been processed into the island-shaped oxide semiconductor layer. In that case, the substrate is taken out of the heating apparatus after the first heat treatment, and then a photolithography step is performed.

The heat treatment which has an effect of dehydrating or dehydrogenating the oxide semiconductor layer may be performed at any of the following timings: after the oxide semiconductor layer is formed; after a conductive film is stacked over the oxide semiconductor layer; after the conductive film is patterned into a source electrode and a drain electrode; and after a gate insulating layer is formed over the source electrode and the drain electrode.

Note that in this embodiment, a conductive film formed using the sputtering target described in Embodiment 1 is provided as the conductive film for forming the source electrode layer and the drain electrode layer. The conductive film is a conductive film in which the hydrogen concentration is reduced; thus, heat treatment is performed after the formation of the conductive film, so that the purity of the oxide semiconductor film can be further increased. In the case where heat treatment is performed after the formation of the conductive film, the temperature of the heat treatment is preferably higher than or equal to 100° C. and lower than 300° C., more preferably 220° C. to 280° C.

Next, a conductive film is formed over the insulating layer 407 and the oxide semiconductor layer 412. The conductive film is formed by a sputtering method with the use of the sputtering target described in Embodiment 1. As examples of the material for the conductive film, the following can be given: an element selected from aluminum (Al), chromium (Cr), copper (Cu), tantalum (Ta), titanium (Ti), molybdenum (Mo), and tungsten (W), an alloy containing any of the elements, an alloy film combining the elements, and the like. Alternatively, one or more materials selected from manganese (Mn), magnesium (Mg), zirconium (Zr), beryllium (Be), and thorium (Th) may be used. Note that a metal having a low electronegativity such as aluminum (Al) or magnesium (Mg), a metal compound, or an alloy is preferably used as the material for the conductive film.

Further, the conductive film may have a single-layer structure or a stacked-layer structure of two or more layers. For example, a single-layer structure of an aluminum film containing silicon; a two-layer structure of an aluminum film and a titanium film stacked thereover; a three-layer structure of a titanium film, an aluminum film stacked thereover, and a titanium film stacked thereover; and the like can be given. Alternatively, a film, an alloy film, or a nitride film which contains aluminum (Al) and one or more elements selected from titanium (Ti), tantalum (Ta), tungsten (W), molybdenum (Mo), chromium (Cr), neodymium (Nd), and scandium (Sc) may be used. For example, it is preferable that a conductive film be formed using a metal having a low electronegativity, a metal compound, or an alloy over a conductive film formed using a metal material having low contact resistance with an oxide semiconductor film, such as titanium, tungsten, or molybdenum.

The conductive film formed using the target described in Embodiment 1 is used as the conductive film in this embodiment; thus, impurities such as moisture or hydrogen in the oxide semiconductor layer, at an interface between the oxide semiconductor layer and the conductive film, and in the vicinity thereof are absorbed or adsorbed by the conductive film. Thus, elimination of impurities such as moisture or hydrogen makes it possible to obtain an i-type (intrinsic) oxide semiconductor layer or an oxide semiconductor layer that is as close to an i-type oxide semiconductor layer as possible, to prevent deterioration of the characteristics of the transistor due to the impurities, such as a shift in the threshold voltage, from being promoted, and to reduce off-state current.

Note that in addition to the above structure, heat treatment may be performed in an atmosphere of an inert gas such as nitrogen or a rare gas (e.g., argon or helium) with the conductive film exposed so that moisture or hydrogen adsorbed on a surface of the conductive film or in the conductive film is removed. The temperature range of the heat treatment is higher than or equal to 100° C. and lower than 300° C., preferably 220° C. to 280° C. The above heat treatment allows impurities such as moisture or hydrogen in the oxide semiconductor layer, at the interface between the oxide semiconductor layer and the conductive film, and in the vicinity thereof to be absorbed and adsorbed more easily by the conductive film.

Next, in a second photolithography step, a resist mask is formed over the conductive film and the conductive film is selectively etched, so that the source or drain electrode layer 415a and the source or drain electrode layer 415b are formed, and then the resist mask is removed (see FIG. 3B). Note that end portions of the source electrode layer and the drain electrode layer are preferably in a tapered shape, in which case the coverage with a gate insulating layer that is stacked thereover can be improved.

In this embodiment, as the source or drain electrode layer 415a and the source or drain electrode layer 415b, a titanium film is formed to a thickness of 150 nm by a sputtering method.

Note that in order to prevent the oxide semiconductor layer 412 from being removed and the insulating layer 407 therebelow from being exposed at the time of the etching of the conductive film, each material and etching conditions are adjusted as appropriate.

In this embodiment, a titanium film is used as the conductive film, an In—Ga—Zn—O-based oxide semiconductor is used for the oxide semiconductor layer 412, and an ammonia hydrogen peroxide solution (a mixture of ammonia, water, and a hydrogen peroxide solution) is used as an etchant for the titanium film.

Note that, in the second photolithography step, only part of the oxide semiconductor layer 412 is etched in some cases, so that an oxide semiconductor layer having a groove (a depressed portion) is formed. In addition, the resist mask for forming the source electrode layer 415a and the drain electrode layer 415b may be formed by an ink-jet method. Formation of the resist mask by an inkjet method needs no photomask, which results in a reduction in manufacturing costs.

Ultraviolet light, KrF laser light, or ArF laser light is used for light exposure for forming the resist mask in the second photolithography step. Channel length L of a transistor that is completed later is determined by a distance between bottom ends of the source electrode layer and the drain electrode layer, which are adjacent to each other over the oxide semiconductor layer 412. Note that in the case of a pattern having a channel length L of less than 25 nm, light exposure for forming the resist mask in the second photolithography step is performed using extreme ultraviolet light with an extremely short wavelength of several nanometers to several tens of nanometers. Light exposure using extreme ultraviolet light enables high resolution and deep depth of focus. Thus, the channel length L of the transistor that is completed later can be greater than or equal to 10 nm and less than or equal to 1000 nm and the operation speed of a circuit can be increased and furthermore the value of off-state current is extremely small, so that low power consumption can be achieved.

Next, the gate insulating layer 402 is formed over the insulating layer 407, the oxide semiconductor layer 412, the source or drain electrode layer 415a, and the source or drain electrode layer 415b (see FIG. 3C).

Here, the oxide semiconductor that is made to be an intrinsic oxide semiconductor or a substantially intrinsic oxide semiconductor (the oxide semiconductor that is purified) by removal of impurities is extremely sensitive to the interface state and the interface electric charge; thus, an interface between the oxide semiconductor and the gate insulating film is important. Therefore, the gate insulating film (GI) that is in contact with the purified oxide semiconductor needs to have higher quality.

For example, a high-density plasma CVD method using microwaves (2.45 GHz) is preferably employed, in which case an insulating film which is dense, has high withstand voltage, and has high quality can be formed. The purified oxide semiconductor and the high-quality gate insulating film are in close contact with each other, whereby the interface state can be reduced and favorable interface characteristics can be obtained.

Further, since the insulating film formed with the high-density plasma CVD apparatus can have a uniform thickness, the insulating film has excellent step coverage. Further, with the high-density plasma CVD apparatus, the thickness of a thin insulating film can be controlled precisely.

Needless to say, another film formation method such as a sputtering method or a plasma CVD method can be employed as long as the method enables formation of a good-quality insulating film as a gate insulating film. Further, an insulating film whose film quality and characteristic of an interface between the insulating film and an oxide semiconductor are improved by heat treatment performed after the formation of the insulating film may be formed as a gate insulating film. In any case, any insulating film may be used as long as the insulating film has characteristics of enabling reduction in interface state density of an interface between the insulating film and an oxide semiconductor and formation of a favorable interface as well as having favorable film quality as a gate insulating film.

Further, when an oxide semiconductor containing impurities is subjected to a gate bias-temperature stress test (BT test) at 85° C., at a voltage applied to the gate of 2×10⁶ V/cm, for 12 hours, a bond between the impurity and a main component of the oxide semiconductor is cleaved by a high electric field (B: bias) and a high temperature (T: temperature), and a generated dangling bond induces shift in the threshold voltage (Vₜₕ). In contrast, the present invention makes it possible to obtain a transistor which is stable to a BT test by removing impurities in an oxide semiconductor, especially hydrogen, moisture, and the like as much as possible to obtain a favorable characteristic of an interface between the oxide semiconductor and a gate insulating film as described above.

The gate insulating layer can be formed to have a single-layer structure or a stacked-layer structure using a silicon oxide layer, a silicon nitride layer, a silicon oxynitride layer, a silicon nitride oxide layer, or an aluminum oxide layer.

The gate insulating layer is formed using a high-density plasma CVD apparatus. Here, a high-density plasma CVD apparatus refers to an apparatus which can realize a plasma density of 1×10¹¹/cm³ or higher. For example, plasma is generated by applying a microwave power of 3 kW to 6 kW, so that an insulating film is formed.

A monosilane gas (SiH₄), nitrous oxide (N/0), and a rare gas are introduced into a chamber as a source gas to generate high-density plasma at a pressure of 10 Pa to 30 Pa, so that an insulating film is formed over a substrate having an insulating surface, such as a glass substrate. After that, supply of a monosilane gas may be stopped, and nitrous oxide (N₂O) and a rare gas may be introduced without exposure to the air to perform plasma treatment on a surface of the insulating film. The plasma treatment performed on the surface of the insulating film by introduction of nitrous oxide (N₂O) and a rare gas is performed at least after the insulating film is formed. The insulating film formed through the above process procedure has a small thickness and corresponds to an insulating film whose reliability can be ensured even though it has a thickness less than 100 nm, for example.

The flow ratio of a monosilane gas (SiH₄) to nitrous oxide (N₂O) which are introduced into the chamber is in the range of 1:10 to 1:200. In addition, as a rare gas which is introduced into the chamber, helium, argon, krypton, xenon, or the like can be used. In particular, argon, which is inexpensive, is preferably used.

Unlike an insulating film formed using a conventional parallel plate plasma CVD apparatus in many points, the insulating film formed through the above process procedure has an etching rate which is lower than that of the insulating film formed using the conventional parallel plate plasma CVD apparatus by greater than or equal to 10% or greater than or equal to 20% in the case where the etching rates with the same etchant are compared with each other. Thus, it can be said that the insulating film obtained with a high-density plasma CVD apparatus is a dense film.

In this embodiment, a silicon oxynitride film (also referred to as SiOₓN_{y} (x>y>0)) having a thickness of 100 nm is used as the gate insulating layer 402. The gate insulating layer 402 is formed in such a manner that monosilane (SiH₄), nitrous oxide (N₂O), and argon (Ar) are used as film formation gases at flow rate of SiH₄/N₂O/Ar=250/2500/2500 (sccm) in a high-density plasma CVD apparatus, and plasma is generated by applying a microwave power of 5 kW at a deposition pressure of 30 Pa and a deposition temperature of 325° C.

Alternatively, the gate insulating layer 402 may be formed by a sputtering method. In the case where a silicon oxide film is formed by a sputtering method, a silicon target or a quartz target is used as a target, and oxygen or a mixed gas of oxygen and argon is used as a sputtering gas. The use of a sputtering method makes it possible to prevent the gate insulating layer 402 from containing a large amount of hydrogen.

The gate insulating layer 402 can have a structure in which a silicon oxide layer and a silicon nitride layer are stacked in this order over the source or drain electrode layer 415a and the source or drain electrode layer 415b. For example, the gate insulating layer 402 having a thickness of 100 nm may be formed in such a manner that a silicon oxide layer (SiOₓ (x>0)) having a thickness of 5 nm to 300 nm inclusive (50 nm in this embodiment) is formed as a first gate insulating layer and a silicon nitride layer (SiN_{y} (y>0)) having a thickness of 50 nm to 200 nm inclusive (50 nm in this embodiment) is stacked over the first gate insulating layer as a second gate insulating layer by a sputtering method. For example, a silicon oxide layer with a thickness of 100 nm can be formed by an RF sputtering method in an atmosphere containing oxygen and argon (the flow ratio of oxygen to argon is 1:1 (each flow rate is 25 sccm)), under conditions where the pressure is 0.4 Pa, and the high-frequency power is 1.5 kW.

Next, a resist mask is formed in a third photolithography step, and part of the gate insulating layer 402 is removed by selective etching, so that an opening 421a and an opening 421b that respectively reach the source or drain electrode layer 415a and the source or drain electrode layer 415b are formed (see FIG. 3D).

Next, a conductive film is formed over the gate insulating layer 402 and in and on the openings 421a and 421b. After that, in a fourth photolithography step, the gate electrode layer 411 and the wiring layers 414a and 414b are formed. Note that a resist mask may be formed by an inkjet method. Formation of the resist mask by an inkjet method needs no photomask, which results in a reduction in manufacturing costs.

The gate electrode layer 411, the wiring layers 414a and 414b can be formed to have a single-layer structure or a stacked-layer structure using a metal material such as molybdenum, titanium, chromium, tantalum, tungsten, aluminum, copper, neodymium, or scandium or an alloy material which contains any of these materials as a main component.

For example, as a two-layer structure of each of the gate electrode layer 411, the wiring layer 414a, and the wiring layer 414b, the following structures are preferable: a two-layer structure of an aluminum layer and a molybdenum layer stacked thereover, a two-layer structure of a copper layer and a molybdenum layer stacked thereover, a two-layer structure of a copper layer and a titanium nitride layer or a tantalum nitride layer stacked thereover, and a two-layer structure of a titanium nitride layer and a molybdenum layer. As a three-layer structure, a stack of a tungsten layer or a tungsten nitride layer, a layer of an alloy of aluminum and silicon or an alloy of aluminum and titanium, and a titanium nitride layer or a titanium layer is preferable. Note that the gate electrode layer can be formed using a light-transmitting conductive film. As an example of the light-transmitting conductive film, a light-transmitting conductive oxide or the like can be given.

In this embodiment, as the gate electrode layer 411 and the wiring layers 414a and 414b, a titanium film is formed to a thickness of 150 nm by a sputtering method. Note that the target described in Embodiment 1 may be used as a sputtering target.

Next, second heat treatment (preferably at higher than or equal to 100° C. and lower than 300° C., more preferably, at 220° C. to 280° C.) is performed in an inert gas atmosphere or an oxygen gas atmosphere. In this embodiment, the second heat treatment is performed in a nitrogen atmosphere at 250° C. for one hour. The second heat treatment may be performed after a protective insulating layer or a planarization insulating layer is formed over the transistor 410.

Heat treatment may be further performed at temperature higher than or equal to 100° C. and lower than or equal to 200° C. for greater than or equal to 1 hour and less than or equal to 30 hours in the air. This heat treatment may be performed at a fixed heating temperature. Alternatively, the following change in the heating temperature may be conducted plural times repeatedly: the heating temperature is increased from room temperature to a temperature higher than or equal to 100° C. and lower than or equal to 200° C. and then decreased to room temperature. This heat treatment may be performed under reduced pressure before the formation of the oxide insulating layer. When the heat treatment is performed under reduced pressure, the heat treatment time can be shortened.

Through the above-described steps, the transistor 410 including the oxide semiconductor layer 412 in which the concentration of hydrogen, moisture, hydride, or hydroxide is reduced can be formed (see FIG. 3E).

In addition, a protective insulating layer or a planarization insulating layer for planarization may be formed over the transistor 410. For example, a protective insulating layer can be formed to have a single-layer structure or a stacked-layer structure of a silicon oxide layer, a silicon nitride layer, a silicon oxynitride layer, a silicon nitride oxide layer, or an aluminum oxide layer.

The planarization insulating layer can be formed of a heat-resistant organic material, such as polyimide, acrylic, polyimide amide, benzocyclobutene, polyamide, or epoxy. Other than such organic materials, it is also possible to use a low-dielectric constant material (a low-k material), a siloxane-based resin, PSG (phosphosilicate glass), BPSG (borophosphosilicate glass), or the like. The planarization insulating layer may be formed by stacking a plurality of insulating films formed of these materials.

Note that the siloxane resin corresponds to a resin including a Si—O—Si bond formed using a siloxane-based material as a starting material. The siloxane-based resin may include as a substituent an organic group (e.g., an alkyl group or an aryl group) or a fluoro group. In addition, the organic group may include a fluoro group.

There is no particular limitation on the method for forming the planarization insulating layer, and the planarization insulating layer can be formed, depending on the material, by a method such as a sputtering method, an SOG method, a spin coating method, a dipping method, a spray coating method, or a droplet discharge method (such as an inkjet method, screen printing, or offset printing), or with a tool such as a doctor knife, a roll coater, a curtain coater, or a knife coater.

In the transistor described in this embodiment, the conductive film used for the source electrode layer and the drain electrode layer is formed using the sputtering target described in Embodiment 1. The conductive film is formed in contact with the oxide semiconductor film used as an active layer, so that impurities such as hydrogen or water in the oxide semiconductor film are extracted by the conductive film, which leads to an increase in the purity of the oxide semiconductor film. Further, moisture remaining in the reaction atmosphere is removed at the time of the formation of the oxide semiconductor film, so that the concentration of hydrogen and hydride in the oxide semiconductor film can be further reduced. Accordingly, the oxide semiconductor film can be stabilized.

In the transistor according to one embodiment of the present invention, the carrier density of an oxide semiconductor film used as an active layer is lower than or equal to 1×10¹²/cm³, preferably, lower than or equal to 1×10¹¹/cm³. In other words, the carrier density of the oxide semiconductor layer is lower than or equal to the measurement limit and made as close to zero as possible.

The purified oxide semiconductor layer is used in the transistor as described above, whereby a transistor in which off-state current is reduced to, for example, 1×10⁻¹³ A or lower can be provided.

As an example of a semiconductor material to be compared with an oxide semiconductor, silicon carbide (for example, 4H—SiC) is given. An oxide semiconductor and 4H—SiC has some common features. The carrier density is one example thereof. In accordance with Fermi-Dirac distribution, the density of minority carriers in the oxide semiconductor is estimated to be 1×10⁻⁷/cm³, which is an extremely low value, similarly to 6.7×10⁻¹¹/cm³ in 4H—SiC. In comparison with the intrinsic carrier density (approximately 1.4×10¹⁰/cm³) of silicon, it is well understood that the degree is extraordinary.

In addition, since the energy band gap of an oxide semiconductor is 3.0 eV to 3.5 eV and the energy band gap of 4H—SiC is 3.26 eV, an oxide semiconductor and silicon carbide are in common in that both are wide-gap semiconductors.

On the other hand, there is a significant difference between an oxide semiconductor and silicon carbide. That is the process temperature. Since heat treatment at 1500° C. to 2000° C. is needed for silicon carbide in general, a stacked-layer structure of silicon carbide and a semiconductor element formed using another semiconductor material is difficult to be formed. This is because a semiconductor substrate or a semiconductor element is destroyed with such high temperature. In contrast, an oxide semiconductor can be manufactured through heat treatment at 300° C. to 500° C. (lower than or equal to the glass transition temperature, approximately 700° C. at maximum); therefore, a semiconductor element can be formed using an oxide semiconductor after an integrated circuit is formed using another semiconductor material.

In addition, in the case of using an oxide semiconductor, there is an advantage that a substrate with low heat resistance such as a glass substrate can be used, which is different from the case of silicon carbide. Moreover, an oxide semiconductor can be deposited without high-temperature heat treatment, so that energy cost can be reduced sufficiently as compared with of the case of using silicon carbide.

An oxide semiconductor is generally considered as an n-type semiconductor; however, according to one embodiment of the invention disclosed herein, an i-type semiconductor is realized by removal of impurities, particularly water or hydrogen. In this respect, it can be said that one embodiment of the invention disclosed herein includes a novel technical idea because the oxide semiconductor according to one embodiment of the invention is made to be i-type in a manner different from that of silicon or the like which is made to be i-type by addition of impurities.

### <Electrical Conduction Mechanism of Transistor Including Oxide Semiconductor>

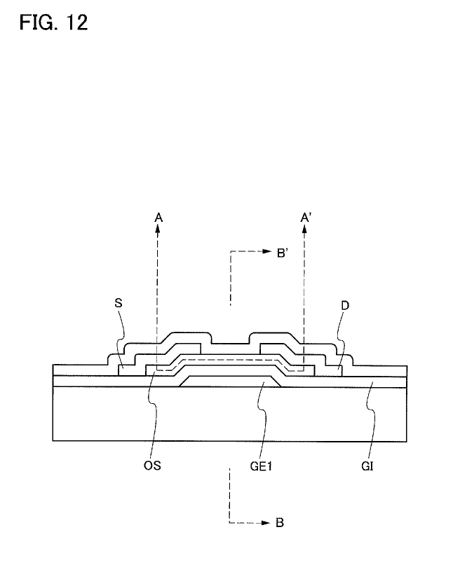

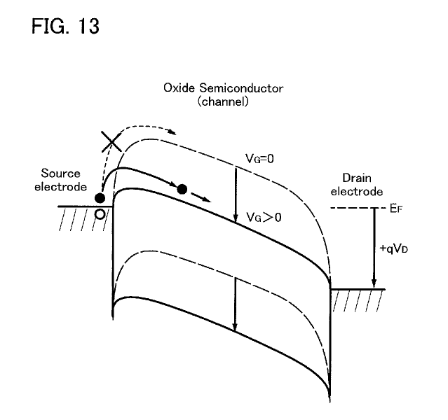

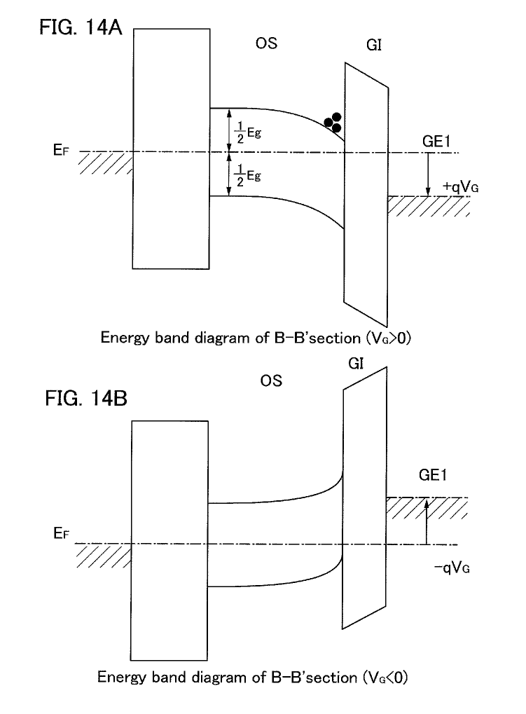

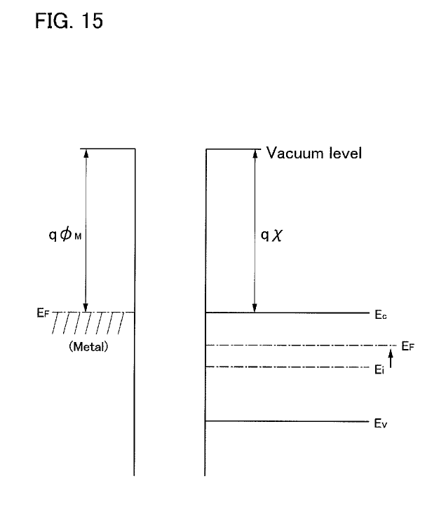

An electrical conduction mechanism of a transistor including an oxide semiconductor will be described with reference to FIG. 12, FIG. 13, FIGS. 14A and 14B, and FIG. 15. Note that the following description is based on the assumption of an ideal situation for easy understanding and does not necessarily reflect a real situation. Note also that the following description is just a consideration and does not affect the validity of the invention.

FIG. 12 is a cross-sectional view of a transistor (thin film transistor) including an oxide semiconductor. An oxide semiconductor layer (OS) is provided over a gate electrode (GE1) with a gate insulating layer (GI) interposed therebetween, and a source electrode (S) and a drain electrode (D) are provided thereover. An insulating layer is provided so as to cover the source electrode (S) and the drain electrode (D).

FIG. 13 is an energy band diagram (schematic diagram) of the A-A′ section in FIG. 12. In FIG. 13, a black circle () and a white circle (◯) represent an electron and a hole and have electric charges (−q, +q), respectively. With a positive voltage (V_{D}>0) applied to the drain electrode, the dashed line shows the case where no voltage is applied to the gate electrode (V_{G}=0) and the solid line shows the case where a positive voltage is applied to the gate electrode (V_{G}>0). In the case where no voltage is applied to the gate electrode, carriers (electrons) are not injected to the oxide semiconductor side from an electrode because of high potential barrier, so that a current does not flow, which means an off state. On the other hand, when a positive voltage is applied to the gate electrode, potential barrier is lowered, and thus a current flows, which means an on state.

FIGS. 14A and 14B are energy band diagrams (schematic diagrams) of the B-B′ section in FIG. 12. FIG. 14A illustrates an on state in which a positive voltage (V_{G}>0) is applied to the gate electrode (GE1) and carriers (electrons) flow between the source electrode and the drain electrode. FIG. 14B illustrates an off state in which a negative voltage (V_{G}<0) is applied to the gate electrode (GE1) and minority carriers do not flow.

FIG. 15 illustrates the relationships between the vacuum level and the work function of a metal (φ_{M}) and between the vacuum level and the electron affinity (χ) of an oxide semiconductor.

At normal temperature, electrons in the metal are degenerated and the Fermi level is located in the conduction band. On the other hand, a conventional oxide semiconductor is an n-type semiconductor, in which the Fermi level (E_{F}) is away from the intrinsic Fermi level (Eᵢ) located in the middle of a band gap and is located closer to the conduction band. Note that it is known that some hydrogen is a donor in an oxide semiconductor and is one factor causing an oxide semiconductor to be an n-type semiconductor.

On the other hand, an oxide semiconductor according to one embodiment of the disclosed invention is an intrinsic (i-type) or a substantially intrinsic oxide semiconductor which is obtained by removing hydrogen that is a factor for an n-type semiconductor from an oxide semiconductor and purifying the oxide semiconductor such that an element other than a main component of the oxide semiconductor (i.e., an impurity element) is prevented from being contained therein as much as possible. In other words, a feature is that a purified i-type (intrinsic) semiconductor, or a semiconductor close thereto, is obtained not by adding an impurity element but by removing an impurity such as hydrogen or water as much as possible. Thus, the Fermi level (E_{F}) can be comparable with the intrinsic Fermi level (Eᵢ).

It is said that the band gap (E_{g}) of an oxide semiconductor is 3.15 eV and the electron affinity (χ) is 4.3 V. The work function of titanium (Ti) included in the source electrode and the drain electrode is substantially equal to the electron affinity (χ) of the oxide semiconductor. In that case, a Schottky barrier for electrons is not formed at an interface between the metal and the oxide semiconductor.

At that time, the electron moves in the vicinity of the interface between the gate insulating layer and the purified oxide semiconductor (the lowest portion of the oxide semiconductor which is stable in terms of energy) as illustrated in FIG. 14A.

In addition, as illustrated in FIG. 14B, when a negative potential is applied to the gate electrode (GE1), the value of current is extremely close to zero because holes that are minority carriers are substantially zero.

In such a manner, an intrinsic (i-type) or substantially intrinsic oxide semiconductor is obtained by being purified such that an element other than its main element (i.e., an impurity element) is contained as little as possible. Thus, characteristics of the interface between the oxide semiconductor and the gate insulating layer become obvious. For that reason, the gate insulating layer needs to be able to form a favorable interface with the oxide semiconductor. Specifically, it is preferable to use, for example, an insulating layer formed by a CVD method using high-density plasma generated with a power supply frequency in the range of the VHF band to the microwave band, an insulating layer formed by a sputtering method, or the like.

When the oxide semiconductor is purified and the interface between the oxide semiconductor and the gate insulating layer is made favorable, in the case where the transistor has a channel width (W) of 1×10⁴ μm and a channel length (L) of 3 μm, for example, it is possible to realize an off-state current of 10⁻¹³ A or less and a subthreshold swing (S value) of 0.1 V/dec. (with a 100-nm-thick gate insulating layer).

The oxide semiconductor is purified as described above so as to contain an element other than its main element (i.e., an impurity element) as little as possible, so that the thin film transistor can operate in a favorable manner.

This embodiment can be implemented in appropriate combination with any of the structures of the other embodiments.

### Embodiment 3

In this embodiment, an example of manufacturing a transistor as a semiconductor device which is manufactured using the target in Embodiment 1 will be described. Note that the same portions as in Embodiment 2 or portions having functions similar to those in Embodiment 2, and steps for forming such portions may be similar to those in Embodiment 2, and description thereof will not be repeated. In a transistor 460 described in this embodiment, a conductive film which is formed using the sputtering target described in Embodiment 1 can be used as a conductive film for a source electrode and a drain electrode.

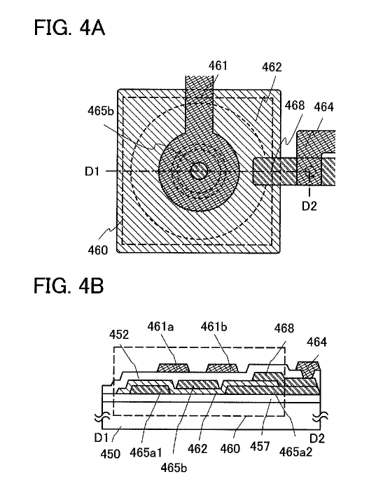

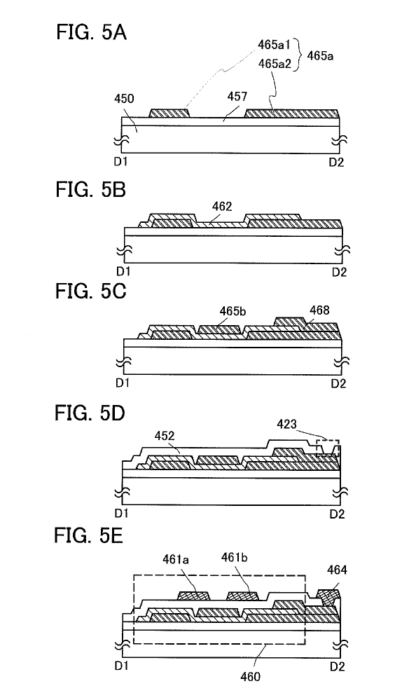

One embodiment of a transistor and one embodiment of a method for manufacturing the transistor in this embodiment will be described with reference to FIGS. 4A and 4B and FIGS. 5A to 5E.

An example of a plan structure and a cross-sectional structure of a transistor are illustrated in FIGS. 4A and 4B, respectively. The transistor 460 illustrated in FIGS. 4A and 4B is one of top-gate transistors.

FIG. 4A is a plan view of the top-gate transistor 460, and FIG. 4B is a cross-sectional view taken along line D1-D2 in FIG. 4A.

The transistor 460 includes an insulating layer 457, a source or drain electrode layer 465a (465a1 and 465a2), an oxide semiconductor layer 462, a source or drain electrode layer 465b, a wiring layer 468, a gate insulating layer 452, and a gate electrode layer 461 (461a and 461b) over a substrate 450 having an insulating surface. The source or drain electrode layer 465a (465a1 and 465a2) is electrically connected to a wiring layer 464 through the wiring layer 468. Further, although not illustrated, the source or drain electrode layer 465b is electrically connected to a wiring layer through an opening provided in the gate insulating layer 452.

Hereinafter, a process of manufacturing the transistor 460 over the substrate 450 will be described with reference to FIGS. 5A to 5E.

First, the insulating layer 457 that serves as a base film is formed over the substrate 450 having an insulating surface.

In this embodiment, a silicon oxide layer is formed as the insulating layer 457 by a sputtering method. The silicon oxide layer is formed as the insulating layer 457 over the substrate 450 in such a manner that the substrate 450 is transferred to a treatment chamber, a sputtering gas which contains high-purity oxygen from which hydrogen and moisture have been removed is introduced, and a silicon target or quartz (preferably synthetic quartz) is used. As a sputtering gas, an oxygen gas or a mixed gas of oxygen and argon is used.

For example, a silicon oxide layer is formed by an RF sputtering method under conditions that the purity of a sputtering gas is 6N; quartz (preferably synthetic quartz) is used; the substrate temperature is 108° C.; the distance between the substrate and the target (the T-S distance) is 60 mm; the pressure is 0.4 Pa; the high frequency power is 1.5 kW; and the atmosphere is an atmosphere containing oxygen and argon (the flow ratio of oxygen to argon is 1:1 (each flow rate is 25 sccm)). The thickness of the silicon oxide layer is 100 nm. Note that instead of quartz (preferably, synthetic quartz), a silicon target can be used as a target for forming the silicon oxide layer.

In that case, the insulating layer 457 is preferably formed while moisture remaining in the treatment chamber is removed in order to prevent hydrogen, hydroxyl groups, or moisture from being contained in the insulating layer 457. From the treatment chamber which is evacuated with a cryopump, a hydrogen atom, a compound containing a hydrogen atom such as water (H₂O), and the like are removed, whereby the concentration of impurities in the insulating layer 457 formed in the treatment chamber can be reduced.

As a sputtering gas used for forming the insulating layer 457, a high-purity gas is preferably used, in which impurities such as hydrogen, water, hydroxyl groups, or hydride are removed so that the concentration is approximately several parts per million or approximately several parts per billion.

The insulating layer 457 may have a stacked-layer structure and, for example, may have a stacked-layer structure in which a nitride insulating layer such as a silicon nitride layer, a silicon nitride oxide layer, an aluminum nitride layer, or an aluminum nitride oxide layer and the above-described oxide insulating layer are stacked in this order over the substrate 450.

For example, a silicon nitride layer is formed using a silicon target by introducing a sputtering gas which contains high-purity nitrogen and from which hydrogen and moisture have been removed, to a space between the silicon oxide layer and the substrate. In this case also, it is preferable that the silicon nitride layer be formed while moisture remaining in the treatment chamber is removed in a manner similar to that of the silicon oxide layer.

Next, a conductive film is formed over the insulating layer 457 by a sputtering method with the use of the sputtering target described in Embodiment 1, a resist mask is formed over the conductive film in a first photolithography step, and the conductive film is selectively etched, so that the source or drain electrode layers 465a1 and 465a2 are formed, and then the resist mask is removed (see FIG. 5A). The source or drain electrode layers 465a1 and 465a2 are a continuous film although illustrated as being separated in the cross-sectional view. Note that end portions of the formed source or drain electrode layers 465a1 and 465a2 are preferably in a tapered shape, in which case the coverage with a gate insulating layer that is stacked thereover can be improved.

As the material for the source or drain electrode layers 465a1 and 465a2, there are an element selected from aluminum (Al), chromium (Cr), copper (Cu), tantalum (Ta), titanium (Ti), molybdenum (Mo), and tungsten (W), an alloy containing any of these elements as a component, an alloy in which any of these elements are combined, and the like. Alternatively, one or more materials selected from manganese (Mn), magnesium (Mg), zirconium (Zr), beryllium (Be), and thorium (Th) may be used. Note that a metal material having lower electronegativity than hydrogen is preferably contained, in which case an effect of extracting impurities from the oxide semiconductor film can be more effective. Further, the conductive film may have a single-layer structure or a stacked-layer structure of two or more layers. For example, a single-layer structure of an aluminum film containing silicon; a two-layer structure of an aluminum film and a titanium film stacked thereover; a three-layer structure in which a titanium film, an aluminum film, and a titanium film are stacked in this order; and the like can be given. Alternatively, a film, an alloy film, or a nitride film of a combination of Al and one or more elements selected from titanium (Ti), tantalum (Ta), tungsten (W), molybdenum (Mo), chromium (Cr), neodymium (Nd), and scandium (Sc) may be used.

In this embodiment, as the source or drain electrode layers 465a1 and 465a2, a titanium film is formed to a thickness of 150 nm by a sputtering method using the target described in Embodiment 1.

Then, an oxide semiconductor film is formed to a thickness greater than or equal to 2 nm and less than or equal to 200 nm over the insulating layer 457.

Next, the oxide semiconductor film is processed into an island-shaped oxide semiconductor layer 462 in a second photolithography step (see FIG. 5B). In this embodiment, the oxide semiconductor film is formed by a sputtering method with the use of an In—Ga—Zn—O-based oxide semiconductor target for film formation.

The oxide semiconductor film is formed over the substrate 450 in such a manner that the substrate is held in a treatment chamber maintained at reduced pressure, a sputtering gas from which hydrogen and moisture have been removed is introduced into the treatment chamber while the moisture remaining therein is removed, metal oxide is used as a target. In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber which is evacuated with a cryopump, a hydrogen atom, a compound containing a hydrogen atom such as water (H₂O) (preferably also a compound containing a carbon atom), and the like are removed, whereby the concentration of impurities in the oxide semiconductor film formed in the treatment chamber can be reduced. Further, the substrate may be heated to 100° C. to 400° C. at the time of forming the oxide semiconductor film.

As a sputtering gas used for forming the oxide semiconductor film, a high-purity gas is preferably used, in which impurities such as hydrogen, water, hydroxyl groups, or hydride are removed so that the concentration is approximately several parts per million or approximately several parts per billion.

As an example of the deposition condition, the following conditions are employed: the distance between the substrate and the target is 110 mm, the pressure is 0.4 Pa, the direct-current (DC) power is 0.5 kW, and the atmosphere is an atmosphere containing oxygen and argon (the flow rate of oxygen is 15 sccm and the flow rate of argon is 30 sccm). Note that a pulsed direct-current (DC) power source is preferably used, in which case powder substances (also referred to as particles or dust) that are generated in deposition can be reduced and the thickness can be uniform. The oxide semiconductor film preferably has a thickness greater than or equal to 5 nm and less than or equal to 30 nm. Note that the appropriate thickness differs depending on the oxide semiconductor material, and the thickness may be set as appropriate depending on the material.

In this embodiment, the oxide semiconductor film is processed into the island-shaped oxide semiconductor layer 462 by a wet etching method using a mixed solution of phosphoric acid, acetic acid, and nitric acid as an etchant.

In this embodiment, first heat treatment is performed on the oxide semiconductor layer 462. The temperature of the first heat treatment is higher than or equal to 100° C. and lower than or equal to 450° C. Here, the substrate is put in an electric furnace that is a kind of heat treatment apparatus and heat treatment is performed on the oxide semiconductor layer at 450° C. in a nitrogen atmosphere for one hour, and then water and hydrogen are prevented from entering the oxide semiconductor layer with the oxide semiconductor layer not exposed to air; thus, the oxide semiconductor layer is obtained. Through the first heat treatment, the oxide semiconductor layer 462 can be dehydrated or dehydrogenated.

The conductive film formed using the target described in Embodiment 1 is used as the conductive film in this embodiment; thus, impurities such as moisture or hydrogen in the oxide semiconductor layer or the insulating layer, at an interface between the oxide semiconductor layer and the insulating layer, and in the vicinity thereof are absorbed or adsorbed by the conductive film. Thus, elimination of impurities such as moisture or hydrogen makes it possible to obtain an i-type (intrinsic) oxide semiconductor layer or an oxide semiconductor layer that is as close to an i-type oxide semiconductor layer as possible, and deterioration of the characteristics of the transistor due to the impurities, such as a shift in the threshold voltage, can be prevented from being promoted and off-state current can be reduced.

Note that the heat treatment apparatus is not limited to an electronic furnace, and may be provided with a device that heats an object by heat conduction or heat radiation from a heating element such as a resistance heating element. For example, a rapid thermal annealing (RTA) apparatus such as a gas rapid thermal annealing (GRTA) apparatus or a lamp rapid thermal annealing (LRTA) apparatus can be used. For example, as the first heat treatment, GRTA may be performed as follows: the substrate is transferred and put in an inert gas which has been heated to a temperature as high as 650° C. to 700° C., heated for several minutes, and transferred and taken out of the inert gas which has been heated to a high temperature. GRTA enables a high-temperature heat treatment in a short time.

Note that in the first heat treatment, it is preferable that water, hydrogen, and the like be not contained in the atmosphere of nitrogen or a rare gas such as helium, neon, or argon. It is preferable that the purity of nitrogen or the rare gas such as helium, neon, or argon which is introduced into a heat treatment apparatus be set to be 6N (99.9999%) or higher, preferably 7N (99.99999%) or higher (that is, the impurity concentration is 1 ppm or lower, preferably 0.1 ppm or lower).

Further, the oxide semiconductor layer might be crystallized to become a microcrystalline film or a polycrystalline film depending on the condition of the first heat treatment or the material for the oxide semiconductor layer.

The first heat treatment for the oxide semiconductor layer can be performed on the oxide semiconductor film that has not been processed into the island-shaped oxide semiconductor layer. In that case, the substrate is taken out of the heating apparatus after the first heat treatment, and then a photolithography step is performed.

The heat treatment having an effect of dehydration or dehydrogenation of the oxide semiconductor layer may be performed at any of the following timings: after the oxide semiconductor layer is formed; after a source electrode and a drain electrode are further stacked over the oxide semiconductor layer; and after a gate insulating layer is formed over the source electrode and the drain electrode.

Next, a conductive film is formed over the insulating layer 457 and the oxide semiconductor layer 462 by a sputtering method with the use of the sputtering target described in Embodiment 1, a resist mask is formed over the conductive film in a third photolithography step, and the conductive film is selectively etched, so that the source or drain electrode layer 465b and the wiring layer 468 are formed, and then the resist mask is removed (see FIG. 5C). The source or drain electrode layer 465b and the wiring layer 468 may be formed using a material and through a step that are similar to those of the source or drain electrode layers 465a1 and 465a2.

In this embodiment, a titanium film with a thickness of 150 nm is formed as the source or drain electrode layer 465b and the wiring layer 468 by a sputtering method. In this embodiment, the same titanium films are used for the source and drain electrode layers 465a1 and 465a2 and the source or drain electrode layer 465b; thus, the etching rate of the source or drain electrode layers 465a1 and 465a2 is the same or substantially the same as that of the source or drain electrode layer 465b. For that reason, the wiring layer 468 is provided over a part of the source or drain electrode layer 465a2 which is not covered with the oxide semiconductor layer 462 so that the source and drain electrode layers 465a1 and 465a2 are prevented from being etched at the time of etching of the source or drain electrode layer 465b. In the case of using different materials which provide high selectivity ratio of the source or drain electrode layer 465b to the source or drain electrode layer 465a1 and 465a2 in the etching step, the wiring layer 468 which protects the source or drain electrode layer 465a2 in etching is not necessarily provided.

Note that in order to prevent the oxide conductive layer 462 from being removed at the time of etching of the conductive film, materials and etching conditions of the conductive film and the oxide semiconductor layer 462 are adjusted as appropriate.

In this embodiment, a titanium film is used as the conductive film, an In—Ga—Zn—O-based oxide semiconductor is used for the oxide semiconductor layer 462, and an ammonia hydrogen peroxide solution (a mixture of ammonia, water, and a hydrogen peroxide solution) is used as an etchant.

Note that, in the third photolithography step, only part of the oxide semiconductor layer 462 is etched in some cases, so that an oxide semiconductor layer having a groove (a depressed portion) is formed. In addition, the resist mask for forming the source or drain electrode layer 465b and the wiring layer 468 may be formed by an ink-jet method. Formation of the resist mask by an inkjet method needs no photomask, which results in a reduction in manufacturing costs.

Next, a gate insulating layer 452 is formed over the insulating layer 457, the oxide semiconductor layer 462, the source or drain electrode layers 465a1 and 465a2, the source or drain electrode layer 465b, and the wiring layer 468.

The gate insulating layer 452 can be formed in a single layer or a stacked layer using a silicon oxide layer, a silicon nitride layer, a silicon oxynitride layer, a silicon nitride oxide layer, or an aluminum oxide layer by a plasma CVD method, a sputtering method, or the like. In order to prevent the gate insulating layer 452 from containing a large amount of hydrogen, the gate insulating layer 452 is preferably formed by a sputtering method. In the case where a silicon oxide film is formed by a sputtering method, a silicon target or a quartz target is used as a target, and oxygen or a mixed gas of oxygen and argon is used as a sputtering gas.

The gate insulating layer 452 can have a structure in which a silicon oxide layer and a silicon nitride layer are stacked in this order over the source or drain electrode layers 465a1 and 465a2 and the source or drain electrode layer 465b. In this embodiment, a silicon oxide layer with a thickness of 100 nm is formed by an RF sputtering method under the conditions that the pressure is 0.4 Pa, the high-frequency power is 1.5 kW, and the atmosphere is an atmosphere containing oxygen and argon (the flow ratio of oxygen to argon is 1:1 (each flow rate is 25 sccm)).

Next, a resist mask is formed in a fourth photolithography step, and part of the gate insulating layer 452 is removed by selective etching, so that an opening 423 that reaches the wiring layer 468 is formed (see FIG. 5D). Although not illustrated, an opening that reaches the source or drain electrode layer 465b may be formed at the time of forming the opening 423. In this embodiment, an example is described in which the opening that reaches the source or drain electrode layer 465b is formed after an interlayer insulating layer is further stacked, and then a wiring layer for electric connection is formed in the opening.

Next, a conductive film is formed over the gate insulating layer 452 and in and on the opening 423. After that, in a fifth photolithography step, the gate electrode layer 461 (461a and 461b) and the wiring layer 464 are formed. Note that a resist mask may be formed by an inkjet method. Formation of the resist mask by an inkjet method needs no photomask, which results in a reduction in manufacturing costs.

The gate electrode layer 461 (461a and 461b) and the wiring layer 464 can be formed to have a single-layer structure or a stacked-layer structure using a metal material such as molybdenum, titanium, chromium, tantalum, tungsten, aluminum, copper, neodymium, or scandium, or an alloy material which contains any of these materials as a main component. The target described in Embodiment 1 may be used as a sputtering target for forming the gate electrode layer 461 (461a and 461b) and the wiring layer 464.

In this embodiment, as the gate electrode layer 461 (461a and 461b) and the wiring layer 464, a titanium film is formed to a thickness of 150 nm by a sputtering method.

Next, second heat treatment (for example, at higher than or equal to 100° C. and lower than 300° C., preferably, at 220° C. to 280° C.) is performed in an inert gas atmosphere or an oxygen gas atmosphere. In this embodiment, the second heat treatment is performed in a nitrogen atmosphere at 250° C. for one hour. The second heat treatment may be performed after a protective insulating layer or a planarization insulating layer is formed over the transistor 460.

Heat treatment may be further performed at temperature higher than or equal to 100° C. and lower than or equal to 200° C. for greater than or equal to 1 hour and less than or equal to 30 hours in the air. This heat treatment may be performed at a fixed heating temperature. Alternatively, the following change in the heating temperature may be conducted plural times repeatedly: the heating temperature is increased from room temperature to a temperature higher than or equal to 100° C. and lower than or equal to 200° C. and then decreased to room temperature. This heat treatment may be performed under reduced pressure before the formation of the oxide insulating layer. When the heat treatment is performed under reduced pressure, the heat treatment time can be shortened.

Through the above-described steps, the transistor 460 including the oxide semiconductor layer 462 in which the concentration of hydrogen, moisture, hydride, or hydroxide is reduced can be formed (see FIG. 5E).

A protective insulating layer or a planarization insulating layer for planarization may be provided over the transistor 460. Although not illustrated, an opening that reaches the source or drain electrode layer 465b is formed in the gate insulating layer 452 and the protective insulating layer or the planarization insulating layer, and a wiring layer that is electrically connected to the source or drain electrode layer 465b is formed in the opening.

In the transistor described in this embodiment, the conductive film used for the source and drain electrode layers is formed using the sputtering target described in Embodiment 1. The conductive film is formed in contact with the oxide semiconductor film, so that impurities such as hydrogen or water in the oxide semiconductor film are extracted by the conductive film, which leads to an increase in the purity of the oxide semiconductor film. Further, moisture remaining in the reaction atmosphere is removed at the time of the formation of the oxide semiconductor film, so that the concentration of hydrogen and hydride in the oxide semiconductor film can be further reduced. Accordingly, the oxide semiconductor film can be stabilized.

The purified oxide semiconductor layer is used in the transistor as described above, whereby a transistor in which off-state current is reduced can be provided.

This embodiment can be implemented in appropriate combination with any of the structures of the other embodiments.

### Embodiment 4

In this embodiment, an example of manufacturing a transistor with the use of the target in Embodiment 1 will be described. Note that the same portions as in Embodiment 2 or portions having functions similar to those in Embodiment 2, and steps for forming such portions may be similar to those in Embodiment 2, and description thereof will not be repeated. In each of transistors 425 and 426 described in this embodiment, a conductive film which is formed using the sputtering target described in Embodiment 1 can be used as a conductive film for the source or drain electrode layer 415a and the source or drain electrode layer 415b.

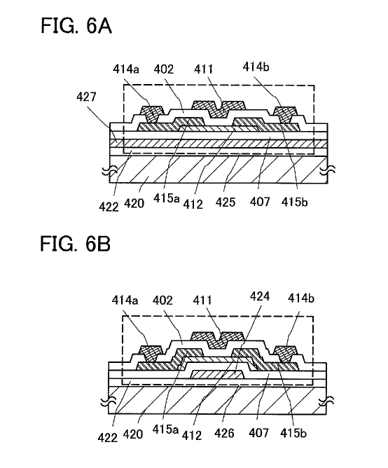

The transistors in this embodiment will be described with reference to FIGS. 6A and 6B.

FIGS. 6A and 6B each illustrate an example of a cross-sectional structure of the transistor. Each of the transistors 425 and 426 illustrated in FIGS. 6A and 6B is a transistor having a structure in which an oxide semiconductor layer is sandwiched between a conductive layer and a gate electrode layer.

In FIGS. 6A and 6B, a silicon substrate is used as a substrate, and the transistors 425 and 426 are provided over an insulating layer 422 that is formed over a silicon substrate 420.

In FIG. 6A, a conductive layer 427 is provided between an insulating layer 407 and the insulating layer 422 provided over the silicon substrate 420, so as to overlap with at least the entire oxide semiconductor layer 412.

Note that FIG. 6B illustrates an example in which a conductive layer between the insulating layer 422 and the insulating layer 407 is processed like a conductive layer 424 by etching and is overlapped with part of the oxide semiconductor layer 412, which includes at least the channel formation region.

As the conductive layers 427 and 424, a metal material which can withstand the temperature of heat treatment performed later may be used; an element selected from titanium (Ti), tantalum (Ta), tungsten (W), molybdenum (Mo), chromium (Cr), neodymium (Nd), and scandium (Sc), an alloy including any of the above elements as a component, an alloy film containing a combination of any of these elements, nitride containing any of the above elements as a component, or the like can be used. In addition, the conductive layers 427 and 424 may each have a single-layer structure or a stacked-layer structure. For example, a single-layer structure of a tungsten layer, a stacked-layer structure including a tungsten nitride layer and a tungsten layer, or the like can be used.

The conductive layers 427 and 424 may have the same potential as or have potential different from that of a gate electrode layer 411 of the transistors 425 and 426 and can function as a second gate electrode layer. In addition, the potential of the conductive layers 427 and 424 may be fixed potential such as GND or 0 V.

The conductive layers 427 and 424 make it possible to control the electric characteristics of the transistors 425 and 426, respectively.

The purified oxide semiconductor layer is used in the transistors as described above, whereby transistors in which off-state current is reduced can be provided.

This embodiment can be implemented in appropriate combination with any of the structures of the other embodiments.

### Embodiment 5

In this embodiment, another example of a transistor manufactured using the target described in Embodiment 1 will be described. In a transistor 390 described in this embodiment, a conductive film formed using the sputtering target described in Embodiment 1 can be used as a conductive film for a source electrode and a drain electrode.

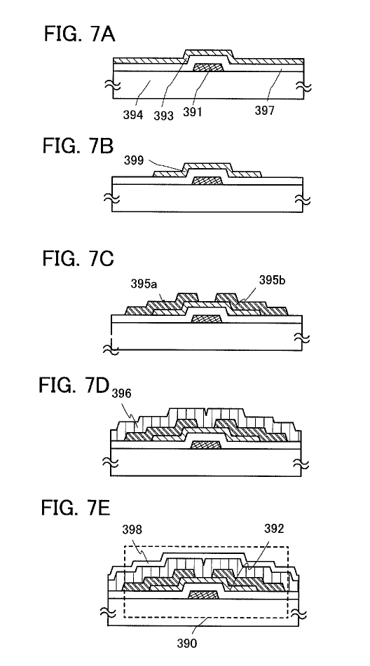

FIGS. 7A to 7E illustrate examples of cross-sectional structures of the transistor in this embodiment. The transistor 390 illustrated in FIG. 7E is a bottom-gate transistor and is also called an inverted staggered transistor.

Although the transistor 390 is described as a single-gate transistor, the transistor 390 can be manufactured as a multi-gate transistor including a plurality of channel formation regions as necessary.

A process of manufacturing the transistor 390 over a substrate 394 will be described below with reference to FIGS. 7A to 7E.

First, a conductive film is formed over the substrate 394 having an insulating surface, and then a gate electrode layer 391 is formed in a first photolithography step. End portions of the formed gate electrode layer are preferably in a tapered shape, in which case the coverage with a gate insulating layer that is stacked thereover can be improved. Note that a resist mask may be formed by an inkjet method. Formation of the resist mask by an inkjet method needs no photomask, which results in a reduction in manufacturing costs.

Although there is no particular limitation on a substrate that can be used as the substrate 394 having an insulating surface, the substrate needs to have at least heat resistance high enough to withstand heat treatment performed later. A glass substrate made of barium borosilicate glass, aluminoborosilicate glass, or the like can be used as the substrate 394 having an insulating surface.

In the case where a glass substrate is used and the temperature of the heat treatment performed later is high, a glass substrate whose strain point is higher than or equal to 730° C. is preferably used. As a material for the glass substrate, a glass material such as aluminosilicate glass, aluminoborosilicate glass, or barium borosilicate glass is used, for example. Note that in general, when a glass substrate contains more barium oxide (BaO) than boron oxide, the glass substrate can be more practical and heat resistant. For that reason, a glass substrate containing BaO and B₂O₃ in which the amount of BaO is larger than that of B₂O₃ is preferably used.

Note that a substrate formed of an insulator, such as a ceramic substrate, a quartz glass substrate, a quartz substrate, or a sapphire substrate, may be used instead of the above glass substrate. Alternatively, a crystallized glass substrate or the like can be used. Further alternatively, a plastic substrate or the like can be used as appropriate.

An insulating film that serves as a base film may be provided between the substrate 394 and the gate electrode layer 391. The base film has a function of preventing diffusion of an impurity element from the substrate 394, and can be formed to have a single-layer structure or a stacked-layer structure using one or more films selected from a silicon nitride film, a silicon oxide film, a silicon nitride oxide film, and a silicon oxynitride film.

The gate electrode layer 391 can be formed to have a single-layer structure or a stacked-layer structure using a metal material such as molybdenum, titanium, chromium, tantalum, tungsten, aluminum, copper, neodymium, or scandium, or an alloy that contains any of these materials as a main component.

As a two-layer structure of the gate electrode layer 391, the following structures are preferable: a two-layer structure in which a molybdenum layer is stacked over an aluminum layer, a two-layer structure in which a molybdenum layer is stacked over a copper layer, a two-layer structure in which a titanium nitride layer or a tantalum nitride layer is stacked over a copper layer, a two-layer structure in which a titanium nitride layer and a molybdenum layer are stacked, and a two-layer structure in which a tungsten nitride layer and a tungsten layer are stacked. As a three-layer structure, a stack of a tungsten layer or a tungsten nitride layer, a layer of an alloy of aluminum and silicon or an alloy of aluminum and titanium, and a titanium nitride layer or a titanium layer is preferable. Note that the gate electrode layer can be formed using a light-transmitting conductive film. As an example of the light-transmitting conductive film, light-transmitting conductive oxide or the like can be given.

Next, a gate insulating layer 397 is formed over the gate electrode layer 391.

The gate insulating layer 397 can be formed to have a single-layer structure or a stacked-layer structure using one or more of a silicon oxide layer, a silicon nitride layer, a silicon oxynitride layer, a silicon nitride oxide layer, and an aluminum oxide layer by a plasma CVD method, a sputtering method, or the like. The gate insulating layer 397 is preferably formed by a sputtering method so that a large amount of hydrogen is prevented from being contained in the gate insulating layer 397. In the case of forming a silicon oxide film by a sputtering method, a silicon target or a quartz target is used as a target, and oxygen or a mixed gas of oxygen and argon is used as a sputtering gas. Alternatively, the sputtering target described in Embodiment 1 can be used as a sputtering target for forming the gate insulating layer.

The gate insulating layer 397 can have a structure in which a silicon nitride layer and a silicon oxide layer are stacked over the gate electrode layer 391 in that order. For example, a silicon nitride layer (SiN_{y}(y>0)) with a thickness greater than or equal to 50 nm and less than or equal to 200 nm (50 nm in this embodiment) is formed as a first gate insulating layer by a sputtering method and a silicon oxide layer (SiOₓ (x>0)) with a thickness greater than or equal to 5 nm and less than or equal to 300 nm (50 nm in this embodiment) is stacked as a second gate insulating layer over the first gate insulating layer, whereby the gate insulating layer with a thickness of 100 nm is formed.

Pretreatment for deposition is preferably performed so that hydrogen, hydroxyl groups, and moisture are contained as little as possible in the gate insulating layer 397 and an oxide semiconductor film 393 formed later. For example, the substrate 394 over which the gate electrode layer 391 is formed or the substrate 394 over which the gate electrode layer 391 and the gate insulating layer 397 are formed is preheated in a preheating chamber in a sputtering apparatus so that impurities such as hydrogen or moisture attached to the substrate 394 are eliminated and removed. The temperature of the preheating is higher than or equal to 100° C. and lower than or equal to 400° C., preferably higher than or equal to 150° C. and lower than or equal to 300° C. As an evacuation unit provided for the preheating chamber, a cryopump is preferably used. This preheating step can be omitted. This preheating may be performed in a similar manner on the substrate 394 over which layers up to and including a source electrode layer 395a and a drain electrode layer 395b are formed before formation of an oxide insulating layer 396.

Next, the oxide semiconductor film 393 is formed to a thickness greater than or equal to 2 nm and less than or equal to 200 nm over the gate insulating layer 397 (see FIG. 7A).

Note that before the oxide semiconductor film 393 is formed by a sputtering method, dust attached to a surface of the gate insulating layer 397 is preferably removed by reverse sputtering in which plasma is generated by introduction of an argon gas. The reverse sputtering is a method in which voltage is applied to a substrate side, not to a target side, using an RF power source in an argon atmosphere and plasma is generated in the vicinity of the substrate so that a substrate surface is modified. Note that a nitrogen atmosphere, a helium atmosphere, an oxygen atmosphere, or the like may be used instead of an argon atmosphere.

The oxide semiconductor film 393 is formed by a sputtering method. As the oxide semiconductor film 393, the following can be used: an In—Ga—Zn—O-based oxide semiconductor film, an In—Sn—Zn—O-based oxide semiconductor film, an In—Al—Zn—O-based oxide semiconductor film, a Sn—Ga—Zn—O-based oxide semiconductor film, an Al—Ga—Zn—O-based oxide semiconductor film, a Sn—Al—Zn—O-based oxide semiconductor film, an In—Sn—O-based oxide semiconductor film, an In—Zn—O-based oxide semiconductor film, a Sn—Zn—O-based oxide semiconductor film, an Al—Zn—O-based oxide semiconductor film, an In—O-based oxide semiconductor film, a Sn—O-based oxide semiconductor film, or a Zn—O-based oxide semiconductor film. In this embodiment, the oxide semiconductor film 393 is formed by a sputtering method using an In—Ga—Zn—O-based oxide semiconductor target for film formation. The oxide semiconductor film 393 can be formed by a sputtering method in a rare gas (typically, argon) atmosphere, an oxygen atmosphere, or a mixed atmosphere of a rare gas (typically, argon) and oxygen. In the case of using a sputtering method, the oxide semiconductor film may be formed using a target containing SiU₂ at greater than or equal to 2 wt % and less than or equal to 10 wt %.

As a target for forming the oxide semiconductor film 393 by a sputtering method, a metal oxide target containing zinc oxide as a main component can be used. As another example of the metal oxide target, an oxide semiconductor target for film formation containing In, Ga, and Zn (the composition ratio of In₂O₃:Ga₂O₃:ZnO=1:1:1 (molar ratio)) or the like can be used. As the oxide semiconductor target for film formation containing In, Ga, and Zn, a target having a composition ratio of In₂O₃:Ga₂O₃:ZnO=1:1:2 (molar ratio) or a target having a composition ratio of In₂O₃:Ga₂O₃:ZnO=1:1:4 (molar ratio) can also be used. In addition, the filling factor of the oxide semiconductor target for film formation is greater than or equal to 90% and less than or equal to 100%, preferably greater than or equal to 95% and less than or equal to 99.9%. An oxide semiconductor film which is formed using an oxide semiconductor target for film formation, which has a high filling factor, is dense.

The oxide semiconductor film 393 is formed over the substrate 394 in such a manner that the substrate is held in a treatment chamber maintained at reduced pressure and is heated to room temperature or a temperature lower than 400° C., then a sputtering gas from which hydrogen and moisture have been removed is introduced into the treatment chamber while moisture remaining therein is removed, and metal oxide is used as a target. In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber which is evacuated with a cryopump, a hydrogen atom, a compound containing a hydrogen atom such as water (H₂O) (preferably also a compound containing a carbon atom), and the like are removed, whereby the concentration of impurities in the oxide semiconductor film formed in the treatment chamber can be reduced. Sputtering film formation is performed while moisture remaining in the treatment chamber is removed using a cryopump, whereby the substrate temperature in forming the oxide semiconductor film 393 can be in the range of room temperature to a temperature lower than 400° C.

As an example of the deposition condition, the following conditions are employed: the distance between the substrate and the target is 100 mm, the pressure is 0.6 Pa, the direct-current (DC) power is 0.5 kW, and the atmosphere is an oxygen atmosphere (the proportion of oxygen flow: 100%). Note that a pulsed direct-current (DC) power source is preferably used, in which case powder substances (also referred to as particles or dust) that are generated in deposition can be reduced and the thickness can be uniform. The oxide semiconductor film preferably has a thickness greater than or equal to 5 nm and less than or equal to 30 nm. Note that the appropriate thickness differs depending on the oxide semiconductor material, and the thickness may be set as appropriate depending on the material.

Examples of a sputtering method include an RF sputtering method in which a high-frequency power source is used for a sputtering power source, a DC sputtering method in which a direct-current power source is used, and a pulsed DC sputtering method in which a bias is applied in a pulsed manner. An RF sputtering method is mainly used in the case where an insulating film is formed, and a DC sputtering method is mainly used in the case where a metal film is formed.

In addition, there is also a multi-source sputtering apparatus in which a plurality of targets of different materials can be set. With the multi-source sputtering apparatus, films of different materials can be formed to be stacked in the same chamber, or a film of plural kinds of materials can be formed by electric discharge at the same time in the same chamber.

In addition, there are a sputtering apparatus provided with a magnet system inside the chamber and used for a magnetron sputtering method, or a sputtering apparatus used for an ECR sputtering method in which plasma generated with the use of microwaves is used without using glow discharge.

Furthermore, as a deposition method using a sputtering method, there are also a reactive sputtering method in which a target substance and a sputtering gas component are chemically reacted with each other during deposition to form a thin compound film thereof, and a bias sputtering method in which voltage is also applied to a substrate during deposition.

Next, in a second photolithography step, the oxide semiconductor film is processed into an island-shaped oxide semiconductor layer 399 (see FIG. 7B). Note that a resist mask for forming the island-shaped oxide semiconductor layer 399 may be formed by an inkjet method. Formation of the resist mask by an inkjet method needs no photomask, which results in a reduction in manufacturing costs.

In the case where a contact hole is formed in the gate insulating layer 397, the contact hole can be formed at the time of the formation of the oxide semiconductor layer 399.

Note that the etching of the oxide semiconductor film 393 here may be performed by dry etching, wet etching, or both wet etching and dry etching.

As an etching gas for dry etching, a gas containing chlorine (chlorine-based gas such as chlorine (Cl₂), boron chloride (BCl₃), silicon chloride (SiCl₄), or carbon tetrachloride (CCl₄)) is preferably used.

Alternatively, a gas containing fluorine (fluorine-based gas such as carbon tetrafluoride (CF₄), sulfur hexafluoride (SF₆), nitrogen trifluoride (NF₃), or trifluoromethane (CHF₃)); hydrogen bromide (HBr); oxygen (O₂); any of these gases to which a rare gas such as helium (He) or argon (Ar) is added; or the like can be used.

As the dry etching method, a parallel plate RIE (reactive ion etching) method or an ICP (inductively coupled plasma) etching method can be used. In order to etch the film into a desired shape, the etching conditions (the amount of electric power applied to a coil-shaped electrode, the amount of electric power applied to an electrode on a substrate side, the temperature of the electrode on the substrate side, and the like) are adjusted as appropriate.

As an etchant used for wet etching, a mixed solution of phosphoric acid, acetic acid, and nitric acid, or the like can be used. Alternatively, ITO07N (produced by KANTO CHEMICAL CO., INC.) may be used.

The etchant used in the wet etching is removed together with the etched materials by cleaning. The waste liquid containing the etchant and the material etched off may be purified and the material may be reused. A material such as indium contained in the oxide semiconductor layer is collected from the waste liquid after the etching and is reused, so that the resources can be efficiently used and the cost can be reduced.

The etching conditions (such as an etchant, etching time, and temperature) are adjusted as appropriate depending on the material so that the oxide semiconductor film can be etched into a desired shape.

Note that before formation of a conductive film in the subsequent step, reverse sputtering is preferably performed so that a resist residue or the like attached to surfaces of the oxide semiconductor layer 399 and the gate insulating layer 397 is removed.

Next, a conductive film is formed over the gate insulating layer 397 and the oxide semiconductor layer 399. The conductive film is formed by a sputtering method with the use of the sputtering target described in Embodiment 1. As examples of the material for the conductive film, an element selected from aluminum (Al), chromium (Cr), copper (Cu), tantalum (Ta), titanium (Ti), molybdenum (Mo), and tungsten (W), an alloy containing any of the elements, an alloy film in which the elements are combined, and the like are given. Alternatively, one or more materials selected from manganese, magnesium, zirconium, beryllium, and thorium may be used. Further, the conductive film may have a single-layer structure or a stacked-layer structure of two or more layers. For example, a single-layer structure of an aluminum film containing silicon; a two-layer structure of an aluminum film and a titanium film stacked thereover; a three-layer structure of a titanium film, an aluminum film stacked thereover, and a titanium film stacked thereover; and the like can be given. Alternatively, a film, an alloy film, or a nitride film which contains aluminum and one or more elements selected from titanium (Ti), tantalum (Ta), tungsten (W), molybdenum (Mo), chromium (Cr), neodymium (Nd), and scandium (Sc) may be used. Note that a material having a low electronegativity is preferably used as the material for the conductive film.

The conductive film formed using the target described in Embodiment 1 is used as the conductive film in this embodiment; thus, impurities such as moisture or hydrogen in the oxide semiconductor layer, the insulating layer, at an interface between the oxide semiconductor layer and the insulating layer, and in the vicinity thereof are absorbed or adsorbed by the conductive film. Thus, elimination of impurities such as moisture or hydrogen makes it possible to obtain an i-type (intrinsic) oxide semiconductor layer or an oxide semiconductor layer that is as close to an i-type oxide semiconductor layer as possible, and deterioration of the characteristics of the transistor due to the impurities, such as a shift in the threshold voltage, can be prevented from being promoted and off-state current can be reduced.

In a third photolithography step, a resist mask is formed over the conductive film and the conductive film is selectively etched, so that a source electrode layer 395a and a drain electrode layer 395b are formed, and then the resist mask is removed (see FIG. 7C).

Ultraviolet light, KrF laser light, or ArF laser light is used for light exposure for forming the resist mask in the third photolithography step. A channel length L of a transistor that is completed later is determined by a distance between bottom ends of the source electrode layer and the drain electrode layer, which are adjacent to each other over the oxide semiconductor layer 399. Note that in the case where light exposure is performed so that a pattern with a channel length L of less than 25 nm is formed, light exposure for forming the resist mask in the third photolithography step is performed using extreme ultraviolet with an extremely short wavelength of several nanometers to several tens of nanometers. Light exposure using extreme ultraviolet enables high resolution and deep depth of focus. Thus, the channel length L of the transistor that is completed later can be greater than or equal to 10 nm and less than or equal to 1000 nm and the operation speed of a circuit can be increased and furthermore the value of off-state current is extremely small, so that lower power consumption can be achieved.

Note that in order to prevent the oxide semiconductor layer 399 from being removed at the time of the etching of the conductive film, materials and etching conditions of the conductive film and the oxide semiconductor layer 399 are adjusted as appropriate.

In this embodiment, a titanium film is used as the conductive film, an In—Ga—Zn—O-based oxide semiconductor is used for the oxide semiconductor layer 399, and an ammonia hydrogen peroxide solution (a mixture of ammonia, water, and a hydrogen peroxide solution) is used as an etchant of the titanium film.

Note that, in the third photolithography step, only part of the oxide semiconductor layer 399 is etched in some cases, so that an oxide semiconductor layer having a groove (a depressed portion) is formed. In addition, the resist mask for forming the source electrode layer 395a and the drain electrode layer 395b may be formed by an ink-jet method. Formation of the resist mask by an inkjet method needs no photomask, which results in a reduction in manufacturing costs.

In order to reduce the number of photomasks and steps in the photolithography step, an etching step may be performed with the use of a multi-tone mask which is a light-exposure mask through which light is transmitted so as to have a plurality of intensities. A resist mask formed with the use of a multi-tone mask has a plurality of thicknesses and further can be changed in shape by etching; thus, the resist mask can be used in a plurality of etching steps for processing into different patterns. Thus, a resist mask corresponding to at least two kinds or more of different patterns can be formed by one multi-tone mask. Thus, the number of light-exposure masks can be reduced and the number of corresponding photolithography steps can also be reduced, whereby simplification of a process can be realized.

Plasma treatment using a gas such as nitrous oxide (N₂O), nitrogen (N₂), or argon (Ar) may be performed to remove water and the like attached to an exposed surface of the oxide semiconductor layer. Alternatively, plasma treatment may be performed using a mixed gas of oxygen and argon.

In the case where the plasma treatment is performed, the oxide insulating layer 396 is formed, without being exposed to air, as an oxide insulating layer that serves as a protective insulating film in contact with part of the oxide semiconductor layer (see FIG. 7D). In this embodiment, the oxide insulating layer 396 is formed so as to be in contact with the oxide semiconductor layer 399 in a region where the oxide semiconductor layer 399 does not overlap with the source electrode layer 395a and the drain electrode layer 395b.

In this embodiment, a silicon oxide layer containing a defect is formed as the oxide insulating layer 396 in such a manner that the substrate 394 over which layers up to and including the island-shaped oxide semiconductor layer 399, the source electrode layer 395a, and the drain electrode layer 395b are formed is heated to room temperature or a temperature lower than 100° C., a sputtering gas which contains high-purity oxygen and from which hydrogen and moisture have been removed is introduced, and a silicon target is used.

For example, the silicon oxide film is formed with a pulsed DC sputtering method under the following conditions: the purity of a sputtering gas is 6N, a boron-doped silicon target (the resistivity is 0.01 Ωcm) is used, the distance between the substrate and the target (T-S distance) is 89 mm, the pressure is 0.4 Pa, the direct-current (DC) power is 6 kW, and the atmosphere is an oxygen atmosphere (the oxygen flow rate is 100%). The thickness of the silicon oxide film is 300 nm. Note that as the target for forming the silicon oxide film, quartz (preferably synthetic quartz) can be used instead of the silicon target. As the sputtering gas, oxygen or a mixed gas of oxygen and argon is used.

In that case, the oxide insulating layer 396 is preferably formed while moisture remaining in the treatment chamber is removed in order to prevent hydrogen, hydroxyl groups, or moisture from being contained in the oxide semiconductor layer 399 and the oxide insulating layer 396.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed; thus, the concentration of impurities in the oxide insulating layer 396 formed in the treatment chamber can be reduced.

Note that as the oxide insulating layer 396, a silicon oxynitride layer, an aluminum oxide layer, an aluminum oxynitride layer, or the like can be used instead of the silicon oxide layer.

Furthermore, heat treatment may be performed at 100° C. to 400° C. with the oxide insulating layer 396 and the oxide semiconductor layer 399 being in contact with each other. Since the oxide insulating layer 396 in this embodiment contains a large number of defects, with this heat treatment, impurities such as hydrogen, moisture, hydroxyl groups, or hydride contained in the oxide semiconductor layer 399 can be diffused into the oxide insulating layer 396, so that the impurities contained in the oxide semiconductor layer 399 are further reduced.

Through the above-described steps, the transistor 390 including the oxide semiconductor layer 392 in which the concentration of hydrogen, moisture, hydroxyl groups, or hydride is reduced can be manufactured (see FIG. 7E).

In the transistor described in this embodiment, the conductive film that is used as the source electrode layer and the drain electrode layer is formed using the sputtering target described in Embodiment 1. The conductive film is formed in contact with the oxide semiconductor film that is used as an active layer, whereby impurities such as hydrogen or water in the oxide semiconductor film are extracted by the conductive film and the purity of the oxide semiconductor film can be increased. In addition, moisture remaining in the atmosphere is removed in forming the oxide semiconductor film, whereby the concentration of hydrogen and hydride in the oxide semiconductor film can be further reduced. Thus, the oxide semiconductor film can be stabilized.

A protective insulating layer may be provided over the oxide insulating layer. In this embodiment, a protective insulating layer 398 is formed over the oxide insulating layer 396. A silicon nitride film, a silicon nitride oxide film, an aluminum nitride film, an aluminum nitride oxide film, or the like is used as the protective insulating layer 398.

As the protective insulating layer 398, a silicon nitride film is formed in such a manner that the substrate 394 over which layers up to and including the oxide insulating layer 396 are formed is heated to a temperature of 100° C. to 400° C., a sputtering gas which contains high-purity nitrogen and from which hydrogen and moisture have been removed is introduced, and a silicon target is used. Also in that case, in a manner similar to that of the oxide insulating layer 396, the protective insulating layer 398 is preferably formed while moisture remaining in the treatment chamber is removed.

In the case where the protective insulating layer 398 is formed, the substrate 394 is heated to 100° C. to 400° C. at the time of the formation of the protective insulating layer 398, whereby hydrogen or moisture contained in the oxide semiconductor layer can be diffused into the oxide insulating layer. In that case, heat treatment does not have to be performed after the formation of the oxide insulating layer 396.

In the case where the silicon oxide layer is formed as the oxide insulating layer 396 and the silicon nitride layer is stacked thereover as the protective insulating layer 398, the silicon oxide layer and the silicon nitride layer can be formed in the same treatment chamber using the same silicon target. First, the silicon oxide layer is formed in such a manner that a gas containing oxygen is introduced and a silicon target provided in the treatment chamber is used. Then, the silicon nitride layer is formed in such a manner that the gas is switched to a gas containing nitrogen and the silicon target used for the silicon nitride layer is used. The silicon oxide layer and the silicon nitride layer can be formed successively without being exposed to air; thus, impurities such as hydrogen or moisture can be prevented from being adsorbed on a surface of the silicon oxide layer. In that case, heat treatment (at 100° C. to 400° C.) is preferably performed so that hydrogen or moisture contained in the oxide semiconductor layer is diffused into the oxide insulating layer, after the silicon oxide layer is formed as the oxide insulating layer 396 and the silicon nitride layer is stacked thereover as the protective insulating layer 398.

After the protective insulating layer is formed, heat treatment may be further performed at temperature higher than or equal to 100° C. and lower than or equal to 200° C. for greater than or equal to 1 hour and less than or equal to 30 hours in the air. This heat treatment may be performed at a fixed heating temperature. Alternatively, the following change in the heating temperature may be conducted plural times repeatedly: the heating temperature is increased from room temperature to a temperature higher than or equal to 100° C. and lower than or equal to 200° C. and then decreased to room temperature. This heat treatment may be performed under reduced pressure before the formation of the oxide insulating layer. When the heat treatment is performed under reduced pressure, the heat treatment time can be shortened. This heat treatment enables a normally-off transistor to be obtained. Thus, the reliability of a semiconductor device can be increased.

Further, moisture remaining in a reaction atmosphere is removed at the time of forming the oxide semiconductor layer that serves as a channel formation region over the gate insulating layer, whereby the concentration of hydrogen and hydride in the oxide semiconductor layer can be reduced

Since the above-described steps are performed at a temperature of 400° C. or lower, the process can be applied to a manufacturing process using a glass substrate having a side longer than or equal to 1 m and a thickness less than or equal to 1 mm. In addition, since all of the above steps can be performed at a treatment temperature of 400° C. or lower, a display panel can be manufactured without consuming too much energy.

As described above, the purified oxide semiconductor layer is used in the transistor, whereby a transistor in which off-state current is reduced can be provided.

This embodiment can be implemented in appropriate combination with any of the structures of the other embodiments.

### Embodiment 6

In this embodiment, another example of a transistor that is manufactured using the target described in Embodiment 1 will be described. In a transistor 310 described in this embodiment, a conductive film formed using the sputtering target described in Embodiment 1 can be used as a conductive film for a source electrode and a drain electrode.

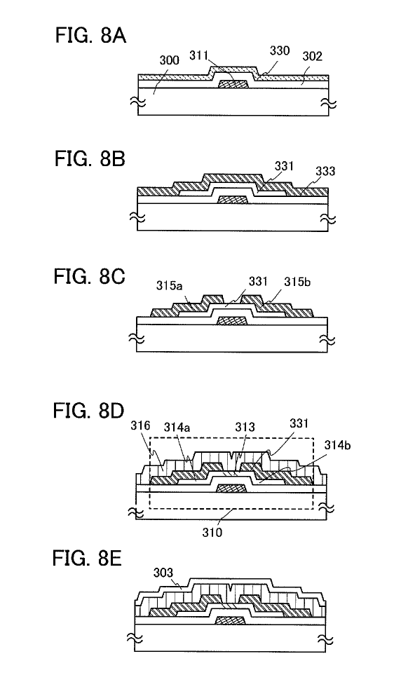

FIGS. 8A to 8E illustrate an example of a cross-sectional structure of the transistor in this embodiment. The transistor 310 illustrated in FIGS. 8A to 8E is one of bottom-gate transistors and is also called an inverted staggered transistor.

Although the transistor 310 is described as a single-gate transistor, a multi-gate transistor including a plurality of channel formation regions can be manufactured when needed.

A process of manufacturing the transistor 310 over a substrate 300 will be described below with reference to FIGS. 8A to 8E.

First, a conductive film is formed over the substrate 300 having an insulating surface, and then a gate electrode layer 311 is formed in a first photolithography step. Note that a resist mask may be formed by an inkjet method. Formation of the resist mask by an inkjet method needs no photomask, which results in a reduction in manufacturing costs.

Although there is no particular limitation on a substrate which can be used as the substrate 300 having an insulating surface, it is necessary that the substrate have at least heat resistance high enough to withstand heat treatment performed later. For example, a glass substrate made of barium borosilicate glass, aluminoborosilicate glass, or the like can be used.

In the case where the temperature of heat treatment performed later is high, a glass substrate whose strain point is higher than or equal to 730° C. is preferably used. As a glass substrate, a glass material such as aluminosilicate glass, aluminoborosilicate glass, or barium borosilicate glass is used, for example. Note that in the case where a larger amount of barium oxide (BaO) than boron oxide is contained, a more practical heat-resistant glass substrate can be obtained. Therefore, a glass substrate containing a larger amount of barium oxide (BaO) than boron oxide (B₂O₃) is preferably used.

Note that a substrate formed of an insulator such as a ceramic substrate, a quartz substrate, or a sapphire substrate may be used instead of the above glass substrate. Alternatively, a crystallized glass substrate or the like can be used.

An insulating film that serves as a base film may be provided between the substrate 300 and the gate electrode layer 311. The base film has a function of preventing diffusion of an impurity element from the substrate 300, and can be formed to have a single-layer or stacked-layer structure using one or more of a silicon nitride film, a silicon oxide film, a silicon nitride oxide film, and a silicon oxynitride film.

Further, the gate electrode layer 311 can be formed to have a single-layer structure or a stacked-layer structure using a metal material such as molybdenum, titanium, chromium, tantalum, tungsten, aluminum, copper, neodymium, or scandium or an alloy material which contains any of these materials as its main component. The gate electrode layer may be formed by a sputtering method with the use of the sputtering target described in Embodiment 1.

Further, the gate electrode layer 311 may have a single-layer structure or a stacked-layer structure of two or more layers. For example, as a two-layer structure of the gate electrode layer 311, the following structure is preferable: a structure in which a molybdenum layer is stacked over an aluminum layer, a structure in which a molybdenum layer is stacked over a copper layer, a structure in which a titanium nitride layer or a tantalum nitride layer is stacked over a copper layer, a structure in which a titanium nitride layer and a molybdenum layer are stacked, or a structure in which a tungsten nitride layer and a tungsten layer are stacked. As a three-layer structure, a structure in which a tungsten layer or a tungsten nitride layer, a layer of an alloy of aluminum and silicon or an alloy of aluminum and titanium, and a titanium nitride layer or a titanium layer are stacked is preferable.

Next, a gate insulating layer 302 is formed over the gate electrode layer 311.

The gate insulating layer 302 can be formed to have a single layer of a silicon oxide layer, a silicon nitride layer, a silicon oxynitride layer, a silicon nitride oxide layer, or an aluminum oxide layer or a stacked layer thereof by a plasma CVD method, a sputtering method, or the like. For example, a silicon oxynitride layer may be formed by a plasma CVD method using SiH₄, oxygen, and nitrogen as a deposition gas. The thickness of the gate insulating layer 302 is greater than or equal to 100 nm and less than or equal to 500 nm. In the case of a stacked-layer structure, for example, a first gate insulating layer with a thickness greater than or equal to 50 nm and less than or equal to 200 nm and a second gate insulating layer with a thickness greater than or equal to 5 nm and less than or equal to 300 nm are stacked in that order.

In this embodiment, a silicon oxynitride layer is formed to a thickness of less than or equal to 100 nm by a plasma CVD method as the gate insulating layer 302.

Next, an oxide semiconductor film 330 is formed to a thickness greater than or equal to 2 nm and less than or equal to 200 nm over the gate insulating layer 302.

Note that before the oxide semiconductor film 330 is formed by a sputtering method, dust attached to a surface of the gate insulating layer 302 is preferably removed by reverse sputtering in which plasma is generated by introduction of an argon gas. Note that a nitrogen atmosphere, a helium atmosphere, an oxygen atmosphere, or the like may be used instead of an argon atmosphere.

As the oxide semiconductor film 330, the following can be used: an In—Ga—Zn—O-based oxide semiconductor film, an In—Sn—Zn—O-based oxide semiconductor film, an In—Al—Zn—O-based oxide semiconductor film, a Sn—Ga—Zn—O-based oxide semiconductor film, an Al—Ga—Zn—O-based oxide semiconductor film, a Sn—Al—Zn—O-based oxide semiconductor film, an In—Sn—O-based oxide semiconductor film, an hi-Zn—O-based oxide semiconductor film, a Sn—Zn—O-based oxide semiconductor film, an Al—Zn—O-based oxide semiconductor film, an In—O-based oxide semiconductor film, a Sn—O-based oxide semiconductor film, or a Zn—O-based oxide semiconductor film. In this embodiment, the oxide semiconductor film 330 is formed by a sputtering method with the use of an In—Ga—Zn—O-based oxide semiconductor target for film formation. A cross-sectional view at this stage is FIG. 8A. The oxide semiconductor film 330 can be formed by a sputtering method in a rare gas (typically, argon) atmosphere, an oxygen atmosphere, or a mixed atmosphere of a rare gas (typically, argon) and oxygen. In the case of using a sputtering method, the oxide semiconductor film may be formed using a target containing SiO₂ at greater than or equal to 2 wt % and less than or equal to 10 wt %.

As a target for forming the oxide semiconductor film 330 by a sputtering method, a metal oxide target containing zinc oxide as a main component can be used. As another example of the metal oxide target, an oxide semiconductor target for film formation containing In, Ga, and Zn (the composition ratio of In₂O₃:Ga₂O₃:ZnO=1:1:1 (molar ratio)) or the like can be used. As the oxide semiconductor target for film formation containing In, Ga, and Zn, a target having a composition ratio of In₂O₃:Ga₂O₃:ZnO=1:1:2 (molar ratio) or a target having a composition ratio of In₂O₃:Ga₂O₃:ZnO=1:1:4 (molar ratio) can also be used. In addition, the filling factor of the oxide semiconductor target for film formation is greater than or equal to 90% and less than or equal to 100%, preferably greater than or equal to 95% and less than or equal to 99.9%. An oxide semiconductor film which is formed using an oxide semiconductor target for film formation, which has a high filling factor, is dense.

As a sputtering gas used for forming the oxide semiconductor film 330, a high-purity gas is preferably used, in which impurities such as hydrogen, water, hydroxyl groups, or hydride are removed so that the concentration is approximately several parts per million or approximately several parts per billion.

The substrate is held in a treatment chamber maintained at reduced pressure and is heated to a temperature higher than or equal to 100° C. and lower than or equal to 600° C., preferably a temperature higher than or equal to 200° C. and lower than or equal to 400° C. Film formation is performed while the substrate is heated, whereby the concentration of impurities contained in the oxide semiconductor film formed can be reduced. In addition, damage due to the sputtering can be reduced. Then, a sputtering gas from which hydrogen and moisture have been removed is introduced into the treatment chamber while moisture remaining therein is removed, and metal oxide is used as a target. In the above manner, the oxide semiconductor film 330 is formed over the gate insulating layer 302. In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber which is evacuated with a cryopump, a hydrogen atom, a compound containing a hydrogen atom such as water (H₂O) (preferably also a compound containing a carbon atom), and the like are removed, whereby the concentration of impurities in the oxide semiconductor film formed in the treatment chamber can be reduced.

As an example of the deposition condition, the following conditions are employed: the distance between the substrate and the target is 100 mm, the pressure is 0.6 Pa, the direct-current (DC) power is 0.5 kW, and the atmosphere is an oxygen atmosphere (the proportion of oxygen flow: 100%). Note that a pulsed direct-current (DC) power source is preferably used, in which case powder substances (also referred to as particles or dust) that are generated in deposition can be reduced and the thickness can be uniform. The oxide semiconductor film preferably has a thickness greater than or equal to 5 nm and less than or equal to 30 nm. Note that the appropriate thickness differs depending on the oxide semiconductor material, and the thickness may be set as appropriate depending on the material.

Next, the oxide semiconductor film 330 is processed into an island-shaped oxide semiconductor layer in a second photolithography step. A resist mask for forming the island-shaped oxide semiconductor layer may be formed by an inkjet method. Formation of the resist mask by an inkjet method needs no photomask, which results in a reduction in manufacturing costs.

Note that the etching of the oxide semiconductor film may be dry etching, without limitation to wet etching.

The etching conditions (such as an etchant, etching time, and temperature) are adjusted as appropriate depending on the material so that the oxide semiconductor film can be etched into a desired shape.

Next, first heat treatment is performed on the oxide semiconductor layer. Through the first heat treatment, the oxide semiconductor layer can be dehydrated or dehydrogenated. The temperature of the first heat treatment is higher than or equal to 400° C. and lower than or equal to 750° C., preferably higher than or equal to 400° C. and lower than the strain point of the substrate. Here, the substrate is put in an electric furnace that is a kind of heat treatment apparatus and heat treatment is performed on the oxide semiconductor layer at 450° C. in a nitrogen atmosphere for one hour, and then water and hydrogen are prevented from entering the oxide semiconductor layer with the oxide semiconductor layer not exposed to air, so that the oxide semiconductor layer 331 is obtained (see FIG. 8B).

The heat treatment apparatus is not limited to an electric furnace and may be provided with a device that heats an object to be processed by thermal conduction or thermal radiation from a heater such as a resistance heater or the like. For example, an RTA (rapid thermal anneal) apparatus such as an LRTA (lamp rapid thermal anneal) apparatus or a GRTA (gas rapid thermal anneal) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus with which heat treatment is performed using a high-temperature gas. As the gas, an inert gas which does not react with an object to be processed by heat treatment, such as nitrogen or a rare gas such as argon is used.

For example, as the first heat treatment, GRTA may be performed as follows: the substrate is transferred and put in an inert gas which has been heated to a temperature as high as 650° C. to 700° C., heated for several minutes, and transferred and taken out of the inert gas which has been heated to a high temperature. GRTA enables a high-temperature heat treatment in a short time.

Note that in the first heat treatment, it is preferable that water, hydrogen, and the like be not contained in the atmosphere of nitrogen or a rare gas such as helium, neon, or argon. It is preferable that the purity of nitrogen or the rare gas such as helium, neon, or argon which is introduced into a heat treatment apparatus be set to be 6N (99.9999%) or higher, preferably 7N (99.99999%) or higher (that is, the impurity concentration is 1 ppm or lower, preferably 0.1 ppm or lower).

Further, the oxide semiconductor layer might be crystallized to become a microcrystalline film or a polycrystalline film depending on the condition of the first heat treatment or the material for the oxide semiconductor layer. For example, the oxide semiconductor layer might be crystallized to become a microcrystalline oxide semiconductor film having a degree of crystallization of 90% or more, or 80% or more. Further, depending on the condition of the first heat treatment and the material for the oxide semiconductor layer, the oxide semiconductor layer might become an amorphous oxide semiconductor film containing no crystalline component. The oxide semiconductor layer may become an oxide semiconductor film in which a microcrystalline portion (with a grain diameter greater than or equal to 1 nm and greater than or less than 20 nm, typically greater than or equal to 2 nm and less than or equal to 4 nm) is mixed into an amorphous oxide semiconductor.

The first heat treatment for the oxide semiconductor layer can be performed on the oxide semiconductor film 330 that has not been processed into the island-shaped oxide semiconductor layer. In that case, the substrate is taken out of the heating apparatus after the first heat treatment, and then a photolithography step is performed.

The heat treatment which has an effect of dehydrating or dehydrogenating the oxide semiconductor layer may be performed at any of the following timings: after the oxide semiconductor layer is formed; after a conductive film is stacked over the oxide semiconductor layer; after the conductive film is processed into a source electrode and a drain electrode; and after a protective insulating film is formed over the source electrode and the drain electrode.

In the case where a contact hole is formed in the gate insulating layer 302, the formation of the contact hole may be performed before or after the dehydration or dehydrogenation of the oxide semiconductor film 330.

In this embodiment, as a conductive film for forming a source electrode layer and a drain electrode layer, a conductive film formed using the sputtering target described in Embodiment 1 is provided. The conductive film is a conductive film in which the hydrogen concentration is reduced; thus, when the conductive film is provided in contact with the oxide semiconductor layer and heat treatment is performed, the purity of the oxide semiconductor layer can be further increased. Note that in the case where heat treatment is performed after the conductive film is formed, the conductive film preferably has heat resistance high enough to withstand the heat treatment. For example, the heating temperature is preferably higher than or equal to 100° C. and lower than 300° C., more preferably 220° C. to 280° C.

Next, a conductive film 333 is formed over the gate insulating layer 302 and the oxide semiconductor layer 331 (see FIG. 8B). The conductive film is formed by a sputtering method with the use of the sputtering target described in Embodiment 1. As examples of the material for the conductive film, an element selected from aluminum (Al), chromium (Cr), copper (Cu), tantalum (Ta), titanium (Ti), molybdenum (Mo), and tungsten (W), an alloy containing any of the elements, an alloy film in which the elements are combined, and the like are given. Alternatively, one or more materials selected from manganese, magnesium, zirconium, beryllium, and thorium may be used. Note that a material having a low electronegativity, specifically a material having a lower electronegativity than hydrogen, is preferably used as a material for the conductive film, in which case an effect of extracting impurities such as hydrogen or moisture from the oxide semiconductor layer can be more effective. Further, the conductive film may have a single-layer structure or a stacked-layer structure of two or more layers. For example, a single-layer structure of an aluminum film containing silicon; a two-layer structure of an aluminum film and a titanium film stacked thereover; a three-layer structure of a titanium film, an aluminum film stacked thereover, and a titanium film stacked thereover; and the like can be given. Alternatively, a film, an alloy film, or a nitride film which contains aluminum and one or more elements selected from titanium (Ti), tantalum (Ta), tungsten (W), molybdenum (Mo), chromium (Cr), neodymium (Nd), and scandium (Sc) may be used.

The conductive film that is formed using the target described in Embodiment 1 is used as the conductive film 333 in this embodiment; thus, impurities such as moisture or hydrogen in the oxide semiconductor layer, at an interface between the oxide semiconductor layer and the conductive film, and in the vicinity thereof are absorbed or adsorbed by the conductive film. Thus, elimination of impurities such as moisture or hydrogen makes it possible to obtain an i-type (intrinsic) oxide semiconductor layer or an oxide semiconductor layer that is as close to an i-type oxide semiconductor layer as possible, and deterioration of the characteristics of the transistor due to the impurities, such as a shift in the threshold voltage, can be prevented from being promoted and off-state current can be reduced.

In a third photolithography step, a resist mask is formed over the conductive film 333 and the conductive film 333 is selectively etched, so that a source electrode layer 315a and a drain electrode layer 315b are formed, and then the resist mask is removed (see FIG. 8C).

Ultraviolet light, KrF laser light, or ArF laser light is used for light exposure for forming the resist mask in the third photolithography step. A channel length L of a transistor that is completed later is determined by a distance between bottom ends of the source electrode layer and the drain electrode layer, which are adjacent to each other over the oxide semiconductor layer 331. Note that in the case where light exposure is performed so that a pattern with a channel length L of less than 25 nm is formed, light exposure for forming the resist mask in the third photolithography step is performed using extreme ultraviolet with an extremely short wavelength of several nanometers to several tens of nanometers. Light exposure using extreme ultraviolet enables high resolution and deep depth of focus. Thus, the channel length L of the transistor that is completed later can be greater than or equal to 10 nm and less than or equal to 1000 nm and the operation speed of a circuit can be increased and furthermore the value of off-state current is extremely small, so that lower power consumption can be achieved.

Note that in order to prevent the oxide semiconductor layer 331 from being removed at the time of the etching of the conductive film, materials and etching conditions of the conductive film and the oxide semiconductor layer 331 are adjusted as appropriate.

In this embodiment, a titanium film is used as the conductive film, an In—Ga—Zn—O-based oxide semiconductor is used for the oxide semiconductor layer 331, and an ammonia hydrogen peroxide solution (a mixture of ammonia, water, and a hydrogen peroxide solution) is used as an etchant of the titanium film.

Note that, in the third photolithography step, only part of the oxide semiconductor layer 331 is etched in some cases, so that an oxide semiconductor layer having a groove (a depressed portion) is formed. In addition, the resist mask for forming the source electrode layer 315a and the drain electrode layer 315b may be formed by an ink-jet method. Formation of the resist mask by an inkjet method needs no photomask, which results in a reduction in manufacturing costs.

Further, an oxide conductive layer may be formed between the oxide semiconductor layer and the source and drain electrode layers. The oxide conductive layer and the metal layer for forming the source and drain electrode layers can be formed successively. The oxide conductive layer can function as a source region and a drain region.

The provision of the oxide conductive layer as the source and drain regions between the oxide semiconductor layer and the source and drain electrode layers makes it possible to decrease the resistance of the source and drain regions and to operate the transistor at high speed.

In order to reduce the number of photomasks and steps in the photolithography step, an etching step may be performed with the use of a multi-tone mask which is a light-exposure mask through which light is transmitted so as to have a plurality of intensities. A resist mask formed with the use of a multi-tone mask has a plurality of thicknesses and further can be changed in shape by etching; thus, the resist mask can be used in a plurality of etching steps for processing into different patterns. Thus, a resist mask corresponding to at least two kinds or more of different patterns can be formed by one multi-tone mask. Thus, the number of light-exposure masks can be reduced and the number of corresponding photolithography steps can also be reduced, whereby simplification of a process can be realized.

Next, plasma treatment using a gas such as nitrous oxide (N₂O), nitrogen (N₂), or argon (Ar) is performed. By this plasma treatment, water or the like attached to an exposed surface of the oxide semiconductor layer is removed. The plasma treatment may be performed using a mixed gas of oxygen and argon.

After the plasma treatment, an oxide insulating layer 316 that serves as a protective insulating film and is in contact with part of the oxide semiconductor layer is formed without exposure to air.

The oxide insulating layer 316 can be formed to a thickness of at least 1 nm by a method with which impurities such as water or hydrogen are not mixed into the oxide insulating layer 316, such as a sputtering method, as appropriate. When hydrogen is contained in the oxide insulating layer 316, entry of the hydrogen to the oxide semiconductor layer or extraction of oxygen in the oxide semiconductor layer by the hydrogen is caused, thereby causing the backchannel of the oxide semiconductor layer to have lower resistance (to be n-type), so that a parasitic channel might be formed. Therefore, it is important that a formation method in which hydrogen is not used be employed in order to form the oxide insulating layer 316 containing as little hydrogen as possible.

In this embodiment, a silicon oxide film is formed to a thickness of 200 nm as the oxide insulating layer 316 by a sputtering method. The substrate temperature in the film formation may be higher than or equal to room temperature and lower than or equal to 300° C., and is 100° C. in this embodiment. The formation of the silicon oxide film by a sputtering method can be performed in an atmosphere of a rare gas (typically, argon), an oxygen atmosphere, or an atmosphere containing oxygen and a rare gas (typically, argon). As a target, a silicon oxide target or a silicon target can be used. For example, with the use of a silicon target, a silicon oxide film can be formed by a sputtering method in an atmosphere containing oxygen and nitrogen. As the oxide insulating layer 316 which is formed in contact with the oxide semiconductor layer whose resistance is reduced, an inorganic insulating film which does not contain impurities such as moisture, a hydrogen ion, and OFF and blocks entry of these from the outside is used. Specifically, a silicon oxide film, a silicon oxynitride film, an aluminum oxide film, an aluminum oxynitride film, or the like is used.

In that case, the oxide insulating layer 316 is preferably formed while moisture remaining in the treatment chamber is removed so that hydrogen, hydroxyl groups, or moisture is prevented from being contained in the oxide semiconductor layer 331 and the oxide insulating layer 316.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed; thus, the concentration of impurities in the oxide insulating layer 316 formed in the treatment chamber can be reduced.

As a sputtering gas used for forming the oxide insulating layer 316, a high-purity gas is preferably used in which impurities such as hydrogen, water, hydroxyl groups, or hydride are removed so that the concentration is approximately several parts per million or approximately several parts per billion.

Next, second heat treatment (preferably at higher than or equal to 200° C. and lower than or equal to 400° C., for example, at higher than or equal to 250° C. and lower than or equal to 350° C.) is performed in an inert gas atmosphere or an oxygen gas atmosphere. For example, the second heat treatment is performed in a nitrogen atmosphere at 250° C. for one hour. By the second heat treatment, heat is applied while part of the oxide semiconductor layer (the channel formation region) is in contact with the oxide insulating layer 316.

Through the above-described steps, first, the first heat treatment for dehydration or dehydrogenation of the formed oxide semiconductor film causes the oxide semiconductor film to be oxygen-deficient and to have lower resistance, that is, causes the oxide semiconductor film to be n-type (e.g., n type). After that, by the second heat treatment in which heat is applied while the oxide insulating layer is in contact with the oxide semiconductor layer, oxygen is supplied to the oxide semiconductor layer 331 whose resistance is reduced by the first heat treatment, whereby an oxygen-deficient portion is repaired. As a result, a channel formation region 313 that overlaps with the gate electrode layer 311 has higher resistance (is i-type), and a high-resistance source region 314a that overlaps with the source electrode layer 315a and a high-resistance drain region 314b that overlaps with the drain electrode layer 315b are formed in a self-aligned manner. Through the above-described steps, the transistor 310 is manufactured (see FIG. 8D).

Further, heat treatment may be performed at higher than or equal to 100° C. and lower than or equal to 200° C. for greater than or equal to 1 hour and less than or equal to 30 hours in the air. In this embodiment, the heat treatment is performed at 150° C. for 10 hours. This heat treatment may be performed at a fixed heating temperature. Alternatively, the following change in the heating temperature may be conducted plural times repeatedly: the heating temperature is increased from room temperature to a temperature higher than or equal to 100° C. and lower than or equal to 200° C. and then decreased to room temperature. This heat treatment may be performed under reduced pressure before the formation of the oxide insulating film. When the heat treatment is performed under reduced pressure, the heat treatment time can be shortened. This heat treatment enables a normally-off transistor to be obtained. Thus, the reliability of a semiconductor device can be increased.

The high-resistance drain region 314b (or the high-resistance source region 314a) is formed in a portion of the oxide semiconductor layer which overlaps with the drain electrode layer 315b (or the source electrode layer 315a), whereby the reliability of the transistor can be increased. Specifically, the formation of the high-resistance drain region 314b enables a structure in which the conductivity can be gradually varied from the drain electrode layer 315b to the channel formation region 313 via the high-resistance drain region 314b. Thus, in the case where the transistor is operated with the drain electrode layer 315b connected to a wiring for supplying a high power supply potential VDD, the high-resistance drain region serves as a buffer and local concentration of an electric field is less likely to occur even if high voltage is applied between the gate electrode layer 311 and the drain electrode layer 315b, whereby the withstand voltage of the transistor can be increased.

Further, the high-resistance source region or the high-resistance drain region in the oxide semiconductor layer is formed in the entire thickness direction in the case where the oxide semiconductor layer is as thin as 15 nm or less. In contrast, in the case where the oxide semiconductor layer is as thick as 30 nm to 50 nm, the resistance of part of the oxide semiconductor layer, that is, a region of the oxide semiconductor layer, which is in contact with the source or drain electrode layer, and the vicinity thereof is decreased, so that the high-resistance source region or the high-resistance drain region is formed and a region of the oxide semiconductor layer which is near the gate insulating layer can be made to be an i-type region.

A protective insulating layer may be additionally formed over the oxide insulating layer 316. For example, a silicon nitride film is formed by an RF sputtering method. Since an RF sputtering method provides high productivity, it is preferably used as a film formation method of the protective insulating layer. As the protective insulating layer, an inorganic insulating film which does not contain impurities such as moisture, a hydrogen ion, and OH⁻ and blocks entry of these from the outside is used; for example, a silicon nitride film, an aluminum nitride film, a silicon nitride oxide film, an aluminum nitride oxide film, or the like is used. In this embodiment, as the protective insulating layer, a protective insulating layer 303 is formed using a silicon nitride film (see FIG. 8E).

In this embodiment, as the protective insulating layer 303, a silicon nitride film is formed in such a manner that the substrate 300 over which layers up to and including the oxide insulating layer 316 are formed is heated to a temperature of 100° C. to 400° C., a sputtering gas which contains high-purity nitrogen and from which hydrogen and moisture have been removed is introduced, and a silicon target is used. Also in that case, in a manner similar to that of the oxide insulating layer 316, the protective insulating layer 303 is preferably formed while moisture remaining in the treatment chamber is removed.

A planarization insulating layer for planarization may be provided over the protective insulating layer 303.

As described above, the purified oxide semiconductor layer is used in the transistor, whereby a transistor in which off-state current is reduced can be provided.

This embodiment can be implemented in appropriate combination with any of the structures of the other embodiments.

### Embodiment 7

In this embodiment, another example of a transistor that is manufactured using the target described in Embodiment 1 will be described. In a transistor 360 described in this embodiment, a conductive film formed using the sputtering target described in Embodiment 1 can be used as a conductive film for a source electrode and a drain electrode.

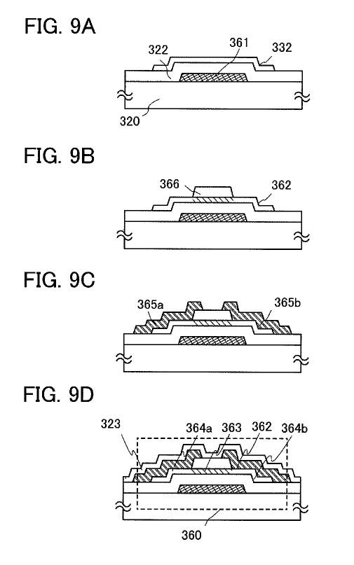

FIGS. 9A to 9D illustrate an example of a cross-sectional structure of the transistor in this embodiment. The transistor 360 illustrated in FIGS. 9A to 9D is one of bottom-gate transistors called channel-protective (channel-stop) transistors and is also called an inverted staggered transistor.

Although the transistor 360 is described as a single-gate transistor, a multi-gate transistor including a plurality of channel formation regions can be manufactured when needed.

A process of manufacturing the transistor 360 over a substrate 320 will be described below with reference to FIGS. 9A to 9D.

First, a conductive film is formed over the substrate 320 having an insulating surface, and then a gate electrode layer 361 is formed in a first photolithography step. Note that a resist mask may be formed by an inkjet method. Formation of the resist mask by an inkjet method needs no photomask, which results in a reduction in manufacturing costs.

The gate electrode layer 361 can be formed to have a single-layer or stacked-layer structure using a metal material such as molybdenum, titanium, chromium, tantalum, tungsten, aluminum, copper, neodymium, or scandium, or an alloy material which contains any of these materials as a main component. Note that the gate electrode layer may be formed by a sputtering method with the use of the sputtering target described in Embodiment 1.

Next, a gate insulating layer 322 is formed over the gate electrode layer 361.

In this embodiment, as the gate insulating layer 322, a silicon oxynitride layer is formed to a thickness of 100 nm or less by a plasma CVD method.

Next, an oxide semiconductor film is formed to a thickness greater than or equal to 2 nm and less than or equal to 200 nm over the gate insulating layer 322, and then the oxide semiconductor film is processed into an island-shaped oxide semiconductor layer in a second photolithography step. In this embodiment, the oxide semiconductor film is formed using an In—Ga—Zn—O-based oxide semiconductor target for film formation by a sputtering method.

In that case, the oxide semiconductor film is preferably formed while moisture remaining in a treatment chamber is removed so that hydrogen, hydroxyl groups, or moisture is contained as little as possible in the oxide semiconductor film.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed; thus, the concentration of impurities in the oxide semiconductor film formed in the treatment chamber can be reduced.

As a sputtering gas used for forming the oxide semiconductor film, a high-purity gas is preferably used, in which impurities such as hydrogen, water, hydroxyl groups, or hydride are removed so that the concentration is approximately several parts per million or approximately several parts per billion.

Next, dehydration or dehydrogenation of the oxide semiconductor layer is performed. The temperature of first heat treatment for dehydration or dehydrogenation is higher than or equal to 400° C. and lower than or equal to 750° C., preferably higher than or equal to 400° C. and lower than the strain point of the substrate. Here, the substrate is put in an electric furnace that is a kind of heat treatment apparatus and heat treatment is performed on the oxide semiconductor layer in a nitrogen atmosphere at 450° C. for one hour, and then water and hydrogen are prevented from entering the oxide semiconductor layer with the oxide semiconductor layer not exposed to air; thus, the oxide semiconductor layer 332 is obtained (see FIG. 9A).

Next, plasma treatment using a gas such as nitrous oxide (N₂O), nitrogen (N₂), or argon (Ar) is performed. By this plasma treatment, water or the like attached to an exposed surface of the oxide semiconductor layer is removed. The plasma treatment may be performed using a mixed gas of oxygen and argon.

Next, an oxide insulating layer is formed over the gate insulating layer 322 and the oxide semiconductor layer 332. After that, in a third photolithography step, a resist mask is formed and the oxide insulating layer is selectively etched, so that an oxide insulating layer 366 is formed. After that, the resist mask is removed.

In this embodiment, as the oxide insulating layer 366, a silicon oxide film is formed to a thickness of 200 nm by a sputtering method. The substrate temperature in the film formation may be higher than or equal to room temperature and lower than or equal to 300° C., and is 100° C. in this embodiment. The formation of the silicon oxide film with a sputtering method can be performed in an atmosphere of a rare gas (typically, argon), an oxygen atmosphere, or an atmosphere containing oxygen and a rare gas (typically, argon). As a target, a silicon oxide target or a silicon target can be used. For example, with the use of a silicon target, a silicon oxide film can be formed by a sputtering method in an atmosphere containing oxygen and nitrogen. As the oxide insulating layer 366 which is formed in contact with the oxide semiconductor layer whose resistance is reduced, an inorganic insulating film which does not contain impurities such as moisture, a hydrogen ion, and OH⁻ and blocks entry of these from the outside is used. Specifically, a silicon oxide film, a silicon oxynitride film, an aluminum oxide film, an aluminum oxynitride film, or the like is used.

In that case, the oxide insulating layer 366 is preferably formed while moisture remaining in the treatment chamber is removed so that hydrogen, hydroxyl groups, or moisture is prevented from being contained in the oxide semiconductor layer 332 and the oxide insulating layer 366.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed; thus, the concentration of impurities in the oxide insulating layer 366 formed in the treatment chamber can be reduced.

As a sputtering gas used for forming the oxide insulating layer 366, a high-purity gas is preferably used, in which impurities such as hydrogen, water, hydroxyl groups, or hydride are removed so that the concentration is approximately several parts per million or approximately several parts per billion.

Next, second heat treatment may be performed in an inert gas atmosphere or an oxygen gas atmosphere (preferably at higher than or equal to 200° C. and lower than or equal to 400° C., for example, at higher than or equal to 250° C. and lower than or equal to 350° C.). For example, the second heat treatment is performed in a nitrogen atmosphere at 250° C. for one hour. By the second heat treatment, heat is applied while part of the oxide semiconductor layer (the channel formation region) is in contact with the oxide insulating layer 366.

In this embodiment, the oxide semiconductor layer 332 which is provided with the oxide insulating layer 366 and is partly exposed is further subjected to heat treatment in a nitrogen atmosphere or an inert gas atmosphere or under reduced pressure. By the heat treatment in a nitrogen atmosphere or an inert gas atmosphere or under reduced pressure, the resistance of the exposed region of the oxide semiconductor layer 332, which is not covered with the oxide insulating layer 366 can be reduced. For example, the heat treatment is performed at 250° C. in a nitrogen atmosphere for one hour.

By the heat treatment performed on the oxide semiconductor layer 332 provided with the oxide insulating layer 366 in a nitrogen atmosphere, the resistance of the exposed region of the oxide semiconductor layer 332 is reduced, so that an oxide semiconductor layer 362 including regions with different resistances (indicated as a shaded region and a white region in FIG. 9B) is formed.

Next, a conductive film is formed over the gate insulating layer 322, the oxide semiconductor layer 362, and the oxide insulating layer 366 with the use of the sputtering target described in Embodiment 1. After that, in a fourth photolithography step, a resist mask is formed and the conductive film is selectively etched, so that a source electrode layer 365a and a drain electrode layer 365b are formed, and then the resist mask is removed (see FIG. 9C).

The conductive film that is formed using the target described in Embodiment 1 is used as the conductive film for forming the source electrode layer 365a and the drain electrode layer 365b in this embodiment; thus, impurities such as moisture or hydrogen in the oxide semiconductor layer, at an interface between the oxide semiconductor layer and the conductive film, and in the vicinity thereof are absorbed or adsorbed by the conductive film. Thus, elimination of impurities such as moisture or hydrogen makes it possible to obtain an i-type (intrinsic) oxide semiconductor layer or an oxide semiconductor layer that is as close to an i-type oxide semiconductor layer as possible, and deterioration of the characteristics of the transistor due to the impurities, such as a shift in the threshold voltage, can be prevented from being promoted and off-state current can be reduced.

As examples of a material for the source electrode layer 365a and the drain electrode layer 365b, an element selected from aluminum (Al), chromium (Cr), copper (Cu), tantalum (Ta), titanium (Ti), molybdenum (Mo), and tungsten (W), an alloy containing any of the elements, an alloy film in which the elements are combined, and the like are given. Further, the conductive film may have a single-layer structure or a stacked-layer structure of two or more layers.

Through the above-described steps, first, the first heat treatment for dehydration or dehydrogenation of the formed oxide semiconductor film causes the oxide semiconductor film to be oxygen-deficient and to have lower resistance, that is, causes the oxide semiconductor film to be n-type (e.g., n type). After that, by the second heat treatment in which heat is applied while the oxide insulating layer is in contact with the oxide semiconductor layer, oxygen is supplied to the oxide semiconductor layer 362 whose resistance is reduced by the first heat treatment, whereby an oxygen-deficient portion is repaired. As a result, a channel formation region 363 that overlaps with the gate electrode layer 361 has higher resistance (is i-type), and a high-resistance source region 364a that overlaps with the source electrode layer 365a and a high-resistance drain region 364b that overlaps with the drain electrode layer 365b are formed in a self-aligned manner. Through the above-described steps, the transistor 360 is manufactured.

Further, heat treatment may be performed at higher than or equal to 100° C. and lower than or equal to 200° C. for greater than or equal to 1 hour and less than or equal to 30 hours in the air. In this embodiment, the heat treatment is performed at 150° C. for 10 hours. This heat treatment may be performed at a fixed heating temperature. Alternatively, the following change in the heating temperature may be conducted plural times repeatedly: the heating temperature is increased from room temperature to a temperature higher than or equal to 100° C. and lower than or equal to 200° C. and then decreased to room temperature. This heat treatment may be performed under reduced pressure before the formation of the oxide insulating film. When the heat treatment is performed under reduced pressure, the heat treatment time can be shortened. This heat treatment enables a normally-off transistor to be obtained. Thus, the reliability of a semiconductor device can be increased.

The high-resistance drain region 364b (or the high-resistance source region 364a) is formed in a portion of the oxide semiconductor layer which overlaps with the drain electrode layer 365b (or the source electrode layer 365a), whereby the reliability of the transistor can be increased. Specifically, the formation of the high-resistance drain region 364b enables a structure in which the conductivity can be gradually varied from the drain electrode layer 365b to the channel formation region 363 via the high-resistance drain region 364b. Thus, in the case where the transistor is operated with the drain electrode layer 365b connected to a wiring for supplying a high power supply potential VDD, the high-resistance drain region serves as a buffer and local concentration of an electric field is less likely to occur even if high voltage is applied between the gate electrode layer 361 and the drain electrode layer 365b, whereby the withstand voltage of the transistor can be increased.

A protective insulating layer 323 is formed over the source electrode layer 365a, the drain electrode layer 365b, and the oxide insulating layer 366. In this embodiment, the protective insulating layer 323 is formed using a silicon nitride film (see FIG. 9D).

Note that an oxide insulating layer may be additionally formed over the source electrode layer 365a, the drain electrode layer 365b, and the oxide insulating layer 366, and a protective insulating layer 323 may be stacked over the oxide insulating layer.

In the transistor described in this embodiment, moisture remaining in the reaction atmosphere is removed in forming the oxide semiconductor film, whereby the concentration of hydrogen and hydride in the oxide semiconductor film can be further reduced. Thus, the oxide semiconductor film can be stabilized.

As described above, the purified oxide semiconductor layer is used in the transistor, whereby a transistor in which off-state current is reduced can be provided.

This embodiment can be implemented in appropriate combination with any of the structures of the other embodiments.

### Embodiment 8

In this embodiment, another example of a transistor that is manufactured using the target described in Embodiment 1 will be described. In a transistor 350 described in this embodiment, a conductive film formed using the sputtering target described in Embodiment 1 can be used as a conductive film for a source electrode and a drain electrode.

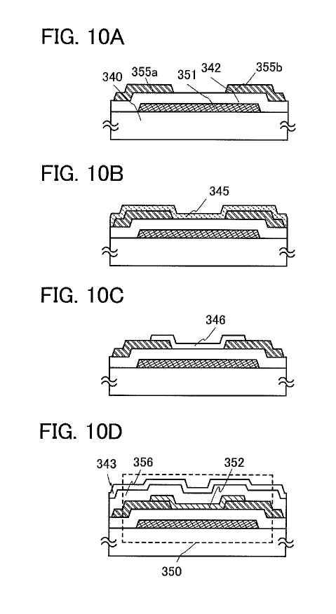

FIGS. 10A to 10D illustrate an example of a cross-sectional structure of the transistor in this embodiment.

Although the transistor 350 is described as a single-gate transistor, a multi-gate transistor including a plurality of channel formation regions can be manufactured when needed.

A process of manufacturing the transistor 350 over a substrate 340 will be described below with reference to FIGS. 10A to 10D.

First, a conductive film is formed over the substrate 340 having an insulating surface, and then a gate electrode layer 351 is formed in a first photolithography step. In this embodiment, as the gate electrode layer 351, a tungsten film is formed to a thickness of 150 nm by a sputtering method. Note that the gate electrode layer may be formed using the sputtering target described in Embodiment 1.

Next, a gate insulating layer 342 is formed over the gate electrode layer 351. In this embodiment, as the gate insulating layer 342, a silicon oxynitride layer is formed to a thickness of 100 nm or less by a plasma CVD method.

Next, a conductive film is formed over the gate insulating layer 342 with the use of the sputtering target described in Embodiment 1, a resist mask is formed over the conductive film in a second photolithography step and the conductive film is selectively etched, so that a source electrode layer 355a and a drain electrode 355b are formed, and then the resist mask is removed (see FIG. 10A).

Next, an oxide semiconductor film 345 is formed (see FIG. 10B). In this embodiment, the oxide semiconductor film 345 is formed using an In—Ga—Zn—O-based oxide semiconductor target for film formation by a sputtering method. The oxide semiconductor film 345 is processed into an island-like oxide semiconductor layer in a third photolithography step.

In that case, the oxide semiconductor film 345 is preferably formed while moisture remaining in the treatment chamber is removed so that hydrogen, hydroxyl groups, or moisture is prevented from being contained in the oxide semiconductor film 345.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed; thus, the concentration of impurities in the oxide semiconductor film 345 formed in the treatment chamber can be reduced.

As a sputtering gas used for forming the oxide semiconductor film 345, a high-purity gas is preferably used, in which impurities such as hydrogen, water, hydroxyl groups, or hydride are removed so that the concentration is approximately several parts per million or approximately several parts per billion.

Next, dehydration or dehydrogenation of the oxide semiconductor layer is performed. Here, the substrate is put in an electric furnace that is a kind of heat treatment apparatus and first heat treatment is performed on the oxide semiconductor layer in a nitrogen atmosphere at 450° C. for one hour, and then water and hydrogen are prevented from entering the oxide semiconductor layer with the oxide semiconductor layer not exposed to air; thus, an oxide semiconductor layer 346 is obtained (see FIG. 10C).

In this embodiment, as the conductive film for forming the source electrode layer and the drain electrode layer, a conductive film formed using the sputtering target described in Embodiment 1 is provided. The conductive film is a conductive film in which the hydrogen concentration is reduced; thus, when the conductive film is provided in contact with the oxide semiconductor layer and the first heat treatment is performed, impurities such as hydrogen or water in the oxide semiconductor layer is extracted by the conductive film, so that the purity of the oxide semiconductor layer can be increased.

As the first heat treatment, GRTA may be performed as follows: the substrate is transferred and put in an inert gas which has been heated to a temperature as high as 650° C. to 700° C., heated for several minutes, and transferred and taken out of the inert gas which has been heated to a high temperature. GRTA enables a high-temperature heat treatment in a short time.

An oxide insulating layer 356 that serves as a protective insulating film is formed in contact with the oxide semiconductor layer 346.

The oxide insulating layer 356 can be formed to a thickness of at least 1 nm by a method with which impurities such as water or hydrogen are not mixed into the oxide insulating layer 356, such as a sputtering method, as appropriate. When hydrogen is contained in the oxide insulating layer 356, entry of the hydrogen to the oxide semiconductor layer or extraction of oxygen in the oxide semiconductor layer by the hydrogen is caused, thereby causing the backchannel of the oxide semiconductor layer to have lower resistance (to be n-type), so that a parasitic channel might be formed. For that reason, it is important that a formation method in which hydrogen is not used be employed in order to form the oxide insulating layer 356 containing as little hydrogen as possible.

In this embodiment, as the oxide insulating layer 356, a silicon oxide film is formed to a thickness of 200 nm by a sputtering method. The substrate temperature in the film formation may be higher than or equal to room temperature and lower than or equal to 300° C., and is 100° C. in this embodiment. The formation of the silicon oxide film by a sputtering method can be performed in an atmosphere of a rare gas (typically, argon), an oxygen atmosphere, or an atmosphere containing oxygen and a rare gas (typically, argon). As a target, a silicon oxide target or a silicon target can be used. For example, with use of a silicon target, a silicon oxide film can be formed by a sputtering method in an atmosphere containing oxygen and nitrogen. As the oxide insulating layer 356 which is formed in contact with the oxide semiconductor layer whose resistance is reduced, an inorganic insulating film which does not contain impurities such as moisture, a hydrogen ion, and OH⁻ and blocks entry of these from the outside is used. Specifically, a silicon oxide film, a silicon oxynitride film, an aluminum oxide film, an aluminum oxynitride film, or the like is used.

In that case, the oxide insulating layer 356 is preferably formed while moisture remaining in the treatment chamber is removed so that hydrogen, hydroxyl groups, or moisture is prevented from being contained in the oxide semiconductor layer 331 and the oxide insulating layer 356.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed; thus, the concentration of impurities in the oxide insulating layer 356 formed in the treatment chamber can be reduced.

As a sputtering gas used for forming the oxide insulating layer 356, a high-purity gas is preferably used, in which impurities such as hydrogen, water, hydroxyl groups, or hydride are removed so that the concentration is approximately several parts per million or approximately several parts per billion.

Next, second heat treatment is performed in an inert gas atmosphere or an oxygen gas atmosphere (preferably at higher than or equal to 200° C. and lower than or equal to 400° C., for example, at higher than or equal to 250° C. and lower than or equal to 350° C.). For example, the second heat treatment is performed in a nitrogen atmosphere at 250° C. for one hour. By the second heat treatment, heat is applied while part of the oxide semiconductor layer (the channel formation region) is in contact with the oxide insulating layer 356.

Through the above-described steps, after the heat treatment for dehydration or dehydrogenation is performed on the formed oxide semiconductor film to reduce the resistance of the oxide semiconductor film, an oxygen-deficient portion of the oxide semiconductor film is repaired. As a result, an oxide semiconductor layer 352 whose resistance is increased (an i-type oxide semiconductor layer) is formed. Through the above-described steps, the transistor 350 is manufactured.

Further, heat treatment may be performed at higher than or equal to 100° C. and lower than or equal to 200° C. for greater than or equal to 1 hour and less than or equal to 30 hours in the air. In this embodiment, the heat treatment is performed at 150° C. for 10 hours. This heat treatment may be performed at a fixed heating temperature. Alternatively, the following change in the heating temperature may be conducted plural times repeatedly: the heating temperature is increased from room temperature to a temperature higher than or equal to 100° C. and lower than or equal to 200° C. and then decreased to room temperature. This heat treatment may be performed under reduced pressure before the formation of the oxide insulating film. When the heat treatment is performed under reduced pressure, the heat treatment time can be shortened. This heat treatment enables a normally-off transistor to be obtained. Thus, the reliability of a semiconductor device can be increased.

A protective insulating layer may be additionally formed over the oxide insulating layer 356. For example, a silicon nitride film is formed by an RF sputtering method. In this embodiment, as the protective insulating layer, a protective insulating layer 343 is formed using a silicon nitride film (see FIG. 10D).

A planarizing insulating layer for planarization may be provided over the protective insulating layer 343.

In the transistor described in this embodiment, the conductive film that is used as the source electrode layer and the drain electrode layer is formed using the sputtering target described in Embodiment 1. The conductive film is formed in contact with the oxide semiconductor film that is used as an active layer, whereby impurities such as hydrogen or water in the oxide semiconductor film are extracted by the conductive film and the purity of the oxide semiconductor can be increased. In addition, moisture remaining in the reaction atmosphere is removed in forming the oxide semiconductor film, whereby the concentration of hydrogen and hydride in the oxide semiconductor film can be further reduced. Thus, the oxide semiconductor film can be stabilized.

As described above, the purified oxide semiconductor layer is used in the transistor, whereby a transistor in which off-state current is reduced can be provided. Further, the transistor described in this embodiment, in which off-state current is reduced is used in, for example, in a pixel in a display device so that a period in which a storage capacitor provided in the pixel can hold voltage can be increased. Thus, a display device which consumes less power in displaying a still image or the like can be provided.

This embodiment can be implemented in appropriate combination with any of the structures of the other embodiments.

### Embodiment 9

In this embodiment, another example of a transistor that is manufactured using the target described in Embodiment 1 will be described. In a transistor 380 described in this embodiment, a conductive film formed using the sputtering target described in Embodiment 1 can be used as a conductive film for a source electrode and a drain electrode.

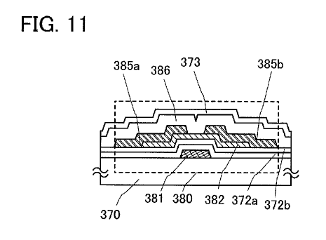

In this embodiment, an example of a manufacturing process of a transistor, which is partly different from that of Embodiment 6, will be described with reference to FIG. 11. Since a manufacturing process of a transistor in FIG. 11 is the same as that of the transistor in FIGS. 8A to 8E except for some steps, the same reference numerals are used for the same portions, and detailed description of the same portions is not given.

In accordance with Embodiment 6, a gate electrode layer 381 is formed over a substrate 370, and a first gate insulating layer 372a and a second gate insulating layer 372b are stacked. In this embodiment, a gate insulating layer has a two-later structure, in which a nitride insulating layer is used as the first gate insulating layer 372a and an oxide insulating layer is used as the second gate insulating layer 372b.

As the oxide insulating layer, a silicon oxide layer, a silicon oxynitride layer, an aluminum oxide layer, an aluminum oxynitride layer, or the like can be used. As the nitride insulating layer, a silicon nitride layer, a silicon nitride oxide layer, an aluminum nitride layer, an aluminum nitride oxide layer, or the like can be used.

In this embodiment, the gate insulating layer has a structure in which a silicon nitride layer and a silicon oxide layer are stacked in this order over the gate electrode layer 381. A silicon nitride layer (SiN_{y} (y>0)) with a thickness greater than or equal to 50 nm and less than or equal to 200 nm (50 nm in this embodiment) is formed as the first gate insulating layer 372a by a sputtering method, and a silicon oxide layer (SiOₓ (x>0)) with a thickness greater than or equal to 5 nm and less than or equal to 300 nm (100 nm in this embodiment) is stacked as the second gate insulating layer 372b over the first gate insulating layer 372a, whereby a gate insulating layer with a thickness of 150 nm is formed.

Next, an oxide semiconductor film is formed and is processed into an island-shaped oxide semiconductor layer in a photolithography step. In this embodiment, the oxide semiconductor film is formed using an In—Ga—Zn—O-based oxide semiconductor target for film formation by a sputtering method.

In that case, the oxide semiconductor film is preferably formed while moisture remaining in the treatment chamber is removed so that hydrogen, hydroxyl groups, or moisture is prevented from being contained in the oxide semiconductor film.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed, whereby the concentration of impurities in the oxide semiconductor film formed in the treatment chamber can be reduced.

As a sputtering gas used for forming the oxide semiconductor film, a high-purity gas is preferably used, in which impurities such as hydrogen, water, hydroxyl groups, or hydride are removed so that the concentration is approximately several parts per million or approximately several parts per billion.

Next, dehydration or dehydrogenation of the oxide semiconductor layer is performed. The temperature of first heat treatment for dehydration or dehydrogenation is higher than or equal to 400° C. and lower than or equal to 750° C., preferably higher than or equal to 425° C. Note that in the case where the temperature is higher than or equal to 425° C., the heat treatment time may be one hour or less, whereas in the case where the temperature is lower than 425° C., the heat treatment time is longer than one hour. Here, the substrate is put in an electric furnace that is a kind of heat treatment apparatus, and heat treatment is performed on the oxide semiconductor layer in a nitrogen atmosphere, and then water and hydrogen are prevented from entering the oxide semiconductor layer with the oxide semiconductor layer not exposed to air; thus, the oxide semiconductor layer is obtained. After that, cooling is performed by introduction of a high-purity oxygen gas, a high-purity nitrous oxide (N₂O) gas, or ultra-dry air (having a dew point of −40° C. or lower, preferably −60° C. or lower) into the same furnace. It is preferable that the oxygen gas and the nitrous oxide (N₂O) gas do not contain water, hydrogen, and the like. Alternatively, the purity of an oxygen gas or a nitrous oxide (N₂O) gas which is introduced into the heat treatment apparatus is preferably 6N (99.9999%) or higher, more preferably 7N (99.99999%) or higher (that is, the impurity concentration of the oxygen gas or the nitrous oxide gas is 1 ppm or lower, preferably 0.1 ppm or lower).

Note that a heat treatment apparatus is not limited to an electric furnace; for example, an RTA (rapid thermal anneal) apparatus such as an LRTA (lamp rapid thermal anneal) apparatus or a GRTA (gas rapid thermal anneal) apparatus can be used. An LRTA apparatus is an apparatus for heating an object to be processed by radiation of light (electromagnetic waves) emitted from a lamp such as a halogen lamp, a metal halide lamp, a xenon arc lamp, a carbon arc lamp, a high pressure sodium lamp, or a high pressure mercury lamp. In addition, the LRTA apparatus may be provided with not only a lamp but also a device for heating an object to be processed by heat conduction or heat radiation from a heater such as a resistance heater. GRTA refers to a method of heat treatment using a high-temperature gas. As the gas, an inert gas which does not react with an object to be processed by heat treatment, such as nitrogen or a rare gas such as argon is used. The heat treatment may be performed at 600° C. to 750° C. for several minutes by an RTA method.

Further, after the first heat treatment for dehydration or dehydrogenation, heat treatment may be performed at higher than or equal to 200° C. and lower than or equal to 400° C., preferably higher than or equal to 200° C. and lower than or equal to 300° C., in an atmosphere of an oxygen gas or a nitrous oxide (N₂O) gas.

The first heat treatment for the oxide semiconductor layer can be performed on the oxide semiconductor film that has not been processed into the island-shaped oxide semiconductor layer. In that case, the substrate is taken out of the heat apparatus after the first heat treatment, and then a photolithography step is performed.

The entire oxide semiconductor film is made to contain an excess amount of oxygen through the above-described steps, whereby the oxide semiconductor film has higher resistance, that is, the oxide semiconductor film becomes an i-type oxide semiconductor film. Thus, an oxide semiconductor layer 382 the entire region of which is an i-type region is obtained.

Next, a conductive film is formed over the gate insulating layers 372a and 372b and the oxide semiconductor layer 382. The conductive film is formed by a sputtering method with the use of the sputtering target described in Embodiment 1. Furthermore, a resist mask is formed over the conductive film in a photolithography step and the conductive film is selectively etched, so that a source electrode layer 385a and a drain electrode layer 385b are formed. Then, an oxide insulating layer 386 is formed by a sputtering method.

In that case, the oxide insulating layer 386 is preferably formed while moisture remaining in the treatment chamber is removed so that hydrogen, hydroxyl groups, or moisture is prevented from being contained in the oxide semiconductor layer 382 and the oxide insulating layer 386.

Note that in this embodiment, as the conductive film for forming the source electrode layer and the drain electrode layer, a conductive film formed using the sputtering target described in Embodiment 1 is provided. The conductive film is a conductive film in which the hydrogen concentration is reduced, and thus can extract impurities such as hydrogen or water in the oxide semiconductor layer or the oxide insulating layer. Note that metal having a lower electronegativity than hydrogen is used as a material used for the conductive film, so that a larger amount of impurities can be extracted.

In order to remove moisture remaining in the treatment chamber, an entrapment vacuum pump is preferably used. For example, a cryopump, an ion pump, or a titanium sublimation pump is preferably used. Further, an evacuation unit may be a turbo pump provided with a cold trap. From the treatment chamber evacuated with a cryopump, for example, a hydrogen atom, a compound containing a hydrogen atom such as water (H₂O), and the like are removed, whereby the concentration of impurities in the oxide insulating layer 386 formed in the treatment chamber can be reduced.

As a sputtering gas used for forming the oxide insulating layer 386, a high-purity gas is preferably used, in which impurities such as hydrogen, water, hydroxyl groups, or hydride are removed so that the concentration is approximately several parts per million or approximately several parts per billion.

Through the above-described steps, the transistor 380 can be manufactured.

Next, in order to reduce variation in the electric characteristics of the transistor, heat treatment (preferably at higher than or equal to 150° C. and lower than 350° C.) may be performed in an inert gas atmosphere or a nitrogen gas atmosphere. For example, the heat treatment is performed at 250° C. in a nitrogen atmosphere for one hour.

Further, heat treatment may be performed at higher than or equal to 100° C. and lower than or equal to 200° C. for greater than or equal to 1 hour and less than or equal to 30 hours. In this embodiment, the heat treatment is performed at 150° C. for 10 hours. This heat treatment may be performed at a fixed heating temperature. Alternatively, the following change in the heating temperature may be conducted plural times repeatedly: the heating temperature is increased from room temperature to a temperature higher than or equal to 100° C. and lower than or equal to 200° C. and then decreased to room temperature. This heat treatment may be performed under reduced pressure before the formation of the oxide insulating layer. When the heat treatment is performed under reduced pressure, the heat treatment time can be shortened. This heat treatment enables a normally-off transistor to be obtained. Thus, the reliability of a semiconductor device can be increased.

A protective insulating layer 373 is formed over the oxide insulating layer 386. In this embodiment, as the protective insulating layer 373, a silicon nitride film is formed to a thickness of 100 nm by a sputtering method.

The protective insulating layer 373 and the first gate insulating layer 372a that are formed of nitride insulating layers do not contain impurities such as moisture, hydrogen, hydride, or hydroxide and have an effect of blocking entry of these impurities from the outside.

Thus, in a manufacturing process after the formation of the protective insulating layer 373, entry of impurities such as moisture from the outside can be prevented. In addition, entry of impurities such as moisture from the outside can be prevented for a long time even after a device is completed as a semiconductor device; thus, the long-term reliability of the device can be improved.

Alternatively, the insulating layers provided between the protective insulating layer 373 and the first gate insulating layer 372a that are formed of nitride insulating layers may be removed, so that the protective insulating layer 373 is in contact with the first gate insulating layer 372a.

Thus, impurities such as moisture, hydrogen, hydride, or hydroxide in the oxide semiconductor layer are reduced to the minimum and entry of the impurities is prevented, so that the concentration of impurities in the oxide semiconductor layer can be kept low.

A planarizing insulating layer for planarization may be provided over the protective insulating layer 373.

In the transistor described in this embodiment, the conductive film that is used as the source electrode layer and the drain electrode layer is formed using the sputtering target described in Embodiment 1. The conductive film is formed in contact with the oxide semiconductor film that is used as an active layer, whereby impurities such as hydrogen or water in the oxide semiconductor film are extracted by the conductive film and the purity of the oxide semiconductor film can be increased. In addition, moisture remaining in the reaction atmosphere is removed in forming the oxide semiconductor film, whereby the concentration of hydrogen and hydride in the oxide semiconductor film can be further reduced. Thus, the oxide semiconductor film can be stabilized.

As described above, the purified oxide semiconductor layer is used in the transistor, whereby a transistor in which off-state current is reduced can be provided. Further, the transistor in which off-state current is reduced is used in, for example, a pixel in a display device, so that a period in which a storage capacitor provided in the pixel can hold voltage can be increased. Thus, a display device which consumes less power in displaying a still image or the like can be provided.

This embodiment can be implemented in appropriate combination with any of the structures of the other embodiments.

### Embodiment 10

In this embodiment, another example of a transistor that is manufactured using the target described in Embodiment 1 will be described. The transistor described in this embodiment can be used as the transistors described in Embodiments 2 to 9.

In this embodiment, an example in which a light-transmitting conductive material is used for a gate electrode layer, a source electrode layer, and a drain electrode layer will be described. Other than the above, the transistor can be manufactured in a manner similar to those of the above embodiments, and description of the same parts or parts having functions and process similar to those in the above embodiments is not given. In addition, detailed description of the same parts is omitted.

As materials for the gate electrode layer, the source electrode layer, and the drain electrode layer, a conductive material that transmits visible light can be used. For example, any of the following metal oxides can be used: an In—Sn—O-based metal oxide; an In—Sn—Zn—O-based metal oxide; an In—Al—Zn—O-based metal oxide; a Sn—Ga—Zn—O-based metal oxide; an Al—Ga—Zn—O-based metal oxide; a Sn—Al—Zn—O-based metal oxide; an In—Zn—O-based metal oxide; a Sn—Zn—O-based metal oxide; an Al—Zn—O-based metal oxide; an In—O-based metal oxide; a Sn—O-based metal oxide; and a Zn—O-based metal oxide. The thickness thereof is set in the range of greater than or equal to 50 nm and less than or equal to 300 nm as appropriate. As a deposition method of the metal oxide used for the gate electrode layer, the source electrode layer, and the drain electrode layer, a sputtering method, a vacuum evaporation method (an electron beam evaporation method or the like), an arc discharge ion plating method, or a spray method is used. In the case where a sputtering method is employed, deposition is preferably performed using a target containing SiO₂ at greater than or equal to 2 wt % and less than or equal to 10 wt %, so that SiOₓ (x>0) which inhibits crystallization is contained in the light-transmitting conductive film; in this way, the oxide semiconductor film can be prevented from being crystallized in heat treatment performed later.

Note that the unit of the percentage of components in the light-transmitting conductive film is atomic percent, and the percentage of components is evaluated by analysis using an electron probe X-ray microanalyzer (EPMA).

In a pixel in which the transistor is provided, when a pixel electrode layer, another electrode layer (such as a capacitor electrode layer), or a wiring layer (such as a capacitor wiring layer) is formed using a conductive film that transmits visible light, a display device having high aperture ratio can be realized. Needless to say, a gate insulating layer, an oxide insulating layer, a protective insulating layer, and a planarization insulating layer in the pixel are also preferably formed using a film that transmits visible light.

In this specification, a film that transmits visible light means a film having a thickness that allows a visible light transmittance of 75% to 100%. In the case where the film has conductivity, the film is also referred to as a transparent conductive film. Further, a conductive film which is semi-transparent to visible light may be used for metal oxide which is used for the gate electrode layer, the source electrode layer, the drain electrode layer, the pixel electrode layer, another electrode layer, or another wiring layer. The conductive film which is semi-transparent to visible light means a film having a visible light transmittance of 50% to 75%.

When the transistor has light-transmitting properties as described above, the aperture ratio can be increased. In particular, for small liquid crystal display panels of 10 inches or smaller, high aperture ratio can be achieved even when the size of pixels is decreased in order to realize higher resolution of display images by, for example, increasing the number of gate wirings. Further, by using a light-transmitting film for components in a transistor, even when a group of high-density transistors is provided, high aperture ratio can be obtained and a sufficient area of a display region can be secured. Further, when a storage capacitor is formed using a material through a step that are the same as those of the component in the transistor, the storage capacitor can also have light-transmitting properties, which results in a further increase in the aperture ratio.

Further, the purified oxide semiconductor layer is used in the transistor, whereby a transistor in which off-state current is reduced can be provided. Further, the transistor in which off-state current is reduced is used in, for example, a pixel in a display device, so that a period in which a storage capacitor provided in the pixel can hold voltage can be increased. Thus, a display device which consumes less power in displaying a still image or the like can be provided.

This embodiment can be implemented in appropriate combination with any of the structures of the other embodiments.

### Embodiment 11

A variety of electronic devices can be completed using a semiconductor device such as the transistors described in Embodiments 2 to 10. In a transistor manufactured using the target described in Embodiment 1, an oxide semiconductor layer whose purity is increased is used as an active layer; thus, off-state current can be reduced. In addition, a transistor which has less variation in the threshold voltage and high reliability can be obtained. Thus, electronic devices as end products can be manufactured with high throughput and high quality.

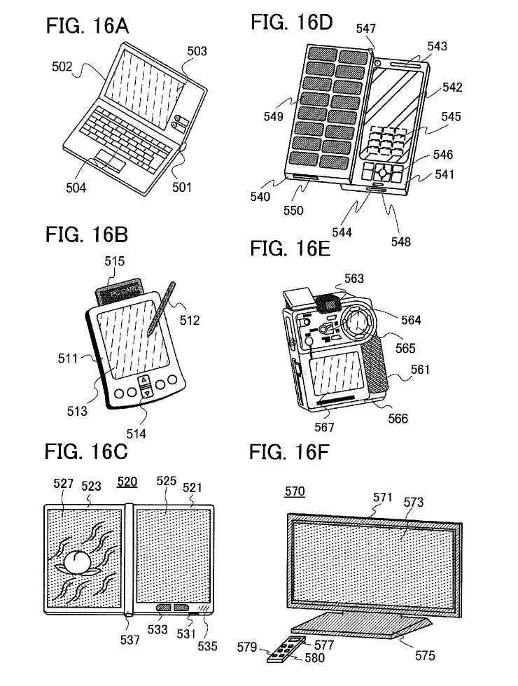

In this embodiment, specific application examples to electronic devices are described with reference to FIGS. 16A to 16F. Note that examples of electronic devices include a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large game machine such as a pinball machine, and the like. Note that the semiconductor devices according to Embodiments 2 to 10 may be integrated to be mounted on a circuit board or the like so as to be incorporated in electronic devices, or can be used as a switching element of a pixel portion. The transistor described in Embodiments 2 to 10 has a small amount of off-state current and less variation in the threshold voltage, and thus can be favorably used in both a pixel portion and a driver circuit portion.

FIG. 16A illustrates a laptop personal computer that includes any of the semiconductor devices according to Embodiments 2 to 10 and includes a main body 501, a housing 502, a display portion 503, keyboard 504, and the like.

FIG. 16B is a portable information terminal (personal digital assistance (PDA)) that includes any of the semiconductor devices according to Embodiments 2 to 10. In a main body 511, a display portion 513, an external interface 515, operation buttons 514, and the like are provided. In addition, the personal information terminal includes a stylus 512 as an accessory for operation.

FIG. 16C illustrates an e-book reader 520 as an example of a device that includes an electronic paper in which any of the semiconductor devices according to Embodiments 2 to 10 is included. The e-book reader 520 includes two housings: a housing 521 and a housing 523. The housing 521 and the housing 523 are combined with a hinge 537 so that the e-book reader 520 can be opened and closed with the hinge 537 as an axis. Such a structure enables the e-book reader 520 to be used like a paper book.

A display portion 525 and a display portion 527 are incorporated in the housing 521 and the housing 523, respectively. The display portion 525 and the display portion 527 may display one image or different images. In the structure where different images are displayed on the display portion 525 and the display portion 527, for example, the right display portion (the display portion 525 in FIG. 16C) can display text and the left display portion (the display portion 527 in FIG. 16C) can display images.

FIG. 16C illustrates an example in which the housing 521 is provided with an operation portion and the like. For example, the housing 521 is provided with a power source 531, operation keys 533, a speaker 535, and the like. Pages can be turned with the operation keys 533. Note that a keyboard, a pointing device, or the like may also be provided on the surface of the housing, on which the display portion is provided. Furthermore, an external connection terminal (an earphone terminal, a USB terminal, a terminal that can be connected to various cables such as an AC adapter and a USB cable, or the like), a recording medium insertion portion, and the like may be provided on the back surface or the side surface of the housing. Further, the e-book reader 520 may have a function of an electronic dictionary.

Further, the e-book reader 520 may send and receive information wirelessly. Through wireless communication, desired book data or the like can be purchased and downloaded from an electronic book server.

Note that electronic paper can be used for electronic devices in all fields as long as the electronic devices display data. An electronic paper can be applied to, for example, posters, advertisement in vehicles such as trains, display in a variety of cards such as credit cards, and the like as well as e-book readers.

FIG. 16D illustrates a mobile phone that includes any of the semiconductor devices according to Embodiments 2 to 10. The mobile phone includes two housings: a housing 540 and a housing 541. The housing 541 is provided with a display panel 542, a speaker 543, a microphone 544, a pointing device 546, a camera lens 547, an external connection terminal 548, and the like. The housing 540 is provided with a solar cell 549 that charges the mobile phone, an external memory slot 550, and the like. In addition, an antenna is incorporated in the housing 541.

The display panel 542 is equipped with a touch panel function. A plurality of operation keys 545 displayed as images are indicated by dashed lines in FIG. 16D. Note that the mobile phone includes a booster circuit for increasing voltage output from the solar cell 549 to voltage needed for each circuit. In addition to the above structure, a contactless IC chip, a small memory device, and the like can be incorporated.

The display orientation of the display panel 542 changes as appropriate in accordance with the usage pattern. Further, the mobile phone is provided with the camera lens 547 on the surface on which the display panel 542 is provided, and thus it can be used as a video phone. The speaker 543 and the microphone 544 can be used for a video phone, recording, playback, and the like without being limited to verbal communication. Moreover, the housings 540 and 541 in a state where they are developed as illustrated in FIG. 16D can be slid so that one is overlapped over the other; therefore, the size of the portable information terminal can be reduced, which makes the portable information terminal suitable for being carried.

The external connection terminal 548 is connectable to an AC adaptor and a variety of cables such as a USB cable, which enables charging of the mobile phone and data communication between the mobile phone a personal computer or the like. Moreover, a larger amount of data can be stored and moved by inserting a recording medium to the external memory slot 550. Further, in addition to the above functions, an infrared communication function, a television reception function, or the like may be provided.

FIG. 16E illustrates a digital camera that includes any of the semiconductor devices according to Embodiments 2 to 10. The digital camera includes a main body 561, a display portion A 567, an eyepiece 563, an operation switch 564, a display portion B 565, a battery 566, and the like.

FIG. 16F illustrates a television set that includes any of the semiconductor devices according to Embodiments 2 to 10. In a television set 570, a display portion 573 is incorporated in a housing 571. Images can be displayed on the display portion 573. Here, the housing 571 is supported by a stand 575.

The television set 570 can be operated with an operation switch of the housing 571 or a separate remote controller 580. Channels and volume can be controlled with operation keys 579 of the remote controller 580 so that an image displayed on the display portion 573 can be controlled. Further, the remote controller 580 may be provided with a display portion 577 for displaying data output from the remote controller 580.

Note that the television set 570 is preferably provided with a receiver, a modem, and the like. With the receiver, a general television broadcast can be received. Moreover, when the display device is connected to a communication network with or without wires via the modem, one-way (from a sender to a receiver) or two-way (between a sender and a receiver, between receivers, or the like) information communication can be performed.

The methods, structures, and the like described in this embodiment can be combined as appropriate with any of the methods, structures, and the like described in the other embodiments.

This application is based on Japanese Patent Application serial no. 2009-260238 filed with Japan Patent Office on Nov. 13, 2009, the entire contents of which are hereby incorporated by reference.

1. A sputtering target which is used for forming a conductive film, comprising:
a sintered body of a metal material having lower electronegativity than an hydrogen,
wherein the concentration of hydrogen contained in the sintered body is lower than or equal to 1×10¹⁶ atoms/cm³.

2. The sputtering target according to claim 1, wherein the filling rate of the sputtering target is greater than or equal to 90% and less than or equal to 100%.

3. A sputtering target which is used for forming a conductive film, comprising:
a sintered body of at least one metal material selected from the group consisting of aluminum, copper, chromium, tantalum, titanium, molybdenum, and tungsten,
wherein the concentration of hydrogen contained in the sintered body is lower than or equal to 1×10¹⁶ atoms/cm³.

4. The sputtering target according to claim 3, wherein the filling rate of the sputtering target is greater than or equal to 90% and less than or equal to 100%.

5. A sputtering target which is used for forming a conductive film, comprising:
a sintered body of a metal material in which silicon, titanium, tantalum, tungsten, molybdenum, chromium, neodymium, scandium, or yttrium is mixed with aluminum at 0.1 at. % to 3 at. %,
wherein the concentration of hydrogen contained in the sintered body is lower than or equal to 1×10¹⁶ atoms/cm³.

6. The sputtering target according to claim 5, wherein the filling rate of the sputtering target is greater than or equal to 90% and less than or equal to 100%.

7. A transistor comprising:
a semiconductor layer; and
a conductive film in contact with the semiconductor layer,
wherein the conductive film comprises a sintered body of a metal material having lower electronegativity than hydrogen, and
wherein the concentration of hydrogen contained in the sintered body is lower than or equal to 1×10¹⁶ atoms/cm³.

8. The transistor according to claim 7, wherein the conductive film is a source electrode or a drain electrode.

9. A transistor comprising:
a semiconductor layer; and
a conductive film in contact with the semiconductor layer,
wherein the conductive film comprises a sintered body of at least one metal material selected from the group consisting of aluminum, copper, chromium, tantalum, titanium, molybdenum, and tungsten, and
wherein the concentration of hydrogen contained in the sintered body is lower than or equal to 1×10¹⁶ atoms/cm³.

10. The transistor according to claim 9, wherein the conductive film is a source electrode or a drain electrode.

11. A transistor comprising:
a semiconductor layer; and
a conductive film in contact with the semiconductor layer,
wherein the conductive film comprises a sintered body of a metal material in which silicon, titanium, tantalum, tungsten, molybdenum, chromium, neodymium, scandium, or yttrium is mixed with aluminum at 0.1 at. % to 3 at. %, and
wherein the concentration of hydrogen contained in the sintered body is lower than or equal to 1×10¹⁶ atoms/cm³.

12. The transistor according to claim 11, wherein the conductive film is a source electrode or a drain electrode.

13. A method for manufacturing a sputtering target, comprising the steps of:
forming a sintered body of a metal material by baking the metal material;
forming a target with a desired shape by machining the sintered body of the metal material;
cleaning the target; and
performing heat treatment on the cleaned target.

14. The method for manufacturing the sputtering target according to claim 13, wherein the metal material is at least one selected from the group consisting of aluminum, copper, chromium, tantalum, titanium, molybdenum, and tungsten.

15. The method for manufacturing the sputtering target according to claim 13, wherein the sintered body contains aluminum mixed silicon, titanium, tantalum, gungsten, molybdenum, chromium, neodymium, scandium, or yttrium at 0.1 at. % to 3 at. %.

16. The method for manufacturing the sputtering target according to claim 13, wherein the concentration of hydrogen contained in the sintered body is lower than or equal to 1×10¹⁶ atoms/cm³.

17. The method for manufacturing the sputtering target according to claim 13, wherein the filling rate of the sputtering target is greater than or equal to 90% and less than or equal to 100%.

18. A method for manufacturing a sputtering target, comprising the steps of:
forming a sintered body of a metal material by baking the metal material;
forming a target with a desired shape by machining the sintered body of the metal material;
cleaning the target;
performing heat treatment on the cleaned target; and
attaching the target to a backing plate.

19. The method for manufacturing the sputtering target according to claim 18, wherein the metal material is at least one selected from the group consisting of aluminum, copper, chromium, tantalum, titanium, molybdenum, and tungsten.

20. The method for manufacturing the sputtering target according to claim 18, wherein the sintered body contains aluminum mixed silicon, titanium, tantalum, gungsten, molybdenum, chromium, neodymium, scandium, or yttrium at 0.1 at. % to 3 at. %.

21. The method for manufacturing the sputtering target according to claim 18, wherein the concentration of hydrogen contained in the sintered body is lower than or equal to 1×10¹⁶ atoms/cm³.

22. The method for manufacturing the sputtering target according to claim 18, wherein the filling rate of the sputtering target is greater than or equal to 90% and less than or equal to 100%.

23. The method for manufacturing the sputtering target according to claim 18, wherein the backing plate is formed using copper, titanium, a copper alloy, or a stainless steel alloy.
